(19) United States
(12) Patent Application Publication
(10) Pub. No.: US 2024/0296319 A1
(43) Pub. Date: Sep. 5, 2024

(54) INTEGRATE-AND-FIRE NEURON CIRCUIT AND OPERATION METHOD THEREOF

(71) Applicant: POSTECH Research and Business Development Foundation, Pohang-si (KR)

(72) Inventors: Chang Ki BAEK, Pohang-si (KR); Yi Joon KIM, Pohang-si (KR); Hyang Woo KIM, Pohang-si (KR)

(73) Assignee: POSTECH Research and Business Development Foundation, Pohang-si (KR)

(21) Appl. No.: 18/544,268

(22) Filed: Dec. 18, 2023

(30) Foreign Application Priority Data
Mar. 2, 2023 (KR) 10-2023-0027658
Nov. 7, 2023 (KR) 10-2023-0152277

(51) Int. Cl. G06N 3/063; H01L 29/165; H01L 29/68; H01L 29/78; H03K 17/567

(52) U.S. Cl. CPC G06N 3/063; H03K 17/567; H01L 29/165; H01L 29/685; H01L 29/78

(57) ABSTRACT

Disclosed are an integrate-and-fire neuron circuit implemented to enable an integrate-and-fire operation with only a small number of devices by using bistable resistance characteristics of the same two heterojunction NPN devices, unlike a CMOS-based integrate-and-fire neuron circuit having a complex structure, and an operation method thereof. In one or more aspects, an integrate-and-fire neuron circuit and an operation method thereof can increase neuron integration in a system by implementing an integrate-and-fire operation of neurons using only three transistors and two capacitors, or two transistors, one resistor and one capacitor, can improve the efficiency of spiking neural network learning by controlling a fire threshold point of neurons through regulation of a gate voltage of the same two NPN devices, and can expect an increase in energy efficiency of the entire system through inhibition of excessive fire by implementing excitatory and inhibitory post-synaptic potentials.

### BACKGROUND

### 1. Field

The present invention relates to an integrate-and-fire neuron circuit and an operation method thereof, and more particularly, to an integrate-and-fire neuron circuit implemented to enable an integrate-and-fire operation with only a small number of devices by using bistable resistance characteristics of the same two heterojunction NPN devices, unlike a CMOS-based integrate-and-fire neuron circuit having a complex structure, and an operation method thereof.

### 2. Description of Related Art

Artificial intelligence based on a deep neural network (hereinafter, referred to as ‘DNN’) has proven excellent learning and cognitive performance at a level of a human brain. However, the DNN is a structure that is inspired by the structure of the brain and simulates a computational process in a software manner. The computations in all stages are performed on hardware suitable for computing of von Neumann architecture, resulting in inefficient energy consumption.

Due to the structure of the existing von Neumann computing architecture where the processor and memory are separated, the existing von Neumann computing architecture is sequentially operated based on data and commands fetched from memory, and when performing an artificial intelligence algorithm using the system, a von Neumann bottleneck phenomenon is defined as a performance limit that occurs between a computational unit and data storage.

To overcome the performance limit, a spiking neural network, which is a third-generation artificial neural network that imitates a biological neural network in a hardware manner, has been proposed. The spiking neural network aims to efficiently imitate a biological spiking neural network mechanism by transmitting synaptic operations and information storage through synapses through an event-based asynchronous spiking operation mechanism and distributing the transmitted synaptic operations and information storage to neurons which are simple computing devices.

An integrate & fire neuron model integrates a current signal received through simulates an operation of transmitting information in the form of a spike when a membrane potential reaches a threshold. The neuron model is an engineering model required for computing a neural network structure, which is the simplest and most versatile model. The early integrate & fire neuron model was implemented in hardware as a CMOS-based circuit.

However, the conventional CMOS-based neuron circuit required a large number of transistors and capacitors to implement an integrate-and-fire operation. As the number of neurons that should be integrated into the system increases to perform high-level functions while consuming less energy, there has been a continued need for a neuron circuit structure and an operation method thereof to improve integration and energy efficiency.

### SUMMARY

The present invention provides an integrate-and-fire neuron circuit capable of enabling high integration by including a simple circuit structure, reducing energy consumption by forming hysteresis with a high current margin in a low voltage range through a heterojunction structure of an NPN device, and realizing a fire frequency of a high-frequency band of neurons by adjusting a resistance state through a control gate of a heterojunction NPN device, and enabling an energy-efficient fire operation by implementing excitatory and inhibitory post-synaptic potentials of biological neurons, and an operation method thereof.

According to an embodiment of the present invention, an integrate-and-fire neuron circuit implementing an integrate-and-fire operation includes: a first NPN device; a second NPN device connected in parallel to the first NPN device; a MOS transistor whose one end is connected to a cathode node of the second NPN device and other end is grounded; a first capacitor connected in parallel to the first NPN device and the second NPN device; and a second capacitor connected in parallel to the cathode node of the second NPN device together with the MOS transistor.

An anode terminal of the first NPN device may be connected in parallel to the first capacitor and an anode terminal of the second NPN device, and a cathode end of the first NPN device may be connected to a ground, and the anode terminal of the second NPN device may be connected in parallel to the first capacitor and the anode terminal of the first NPN device, and a cathode end of the second NPN device may be connected in parallel to the MOS transistor and the second capacitor.

The first NPN device and the second NPN device may include: a first N-type semiconductor; a P-type semiconductor whose one end is heterogeneously bonded to one end of the first N-type semiconductor; a second N-type semiconductor whose one end is heterogeneously bonded to the other end of the P-type semiconductor; a control gate formed on top of the P-type semiconductor; an anode contacting the first N-type semiconductor through an ohmic junction; a cathode contacting the second N-type semiconductor through the ohmic junction; and the first N-type semiconductor and the second N-type semiconductor may have a relatively higher concentration than the P-type semiconductor, and the P-type semiconductor may have a smaller band gap than the first N-type semiconductor and the second N-type semiconductor.

According to an embodiment of the present invention, an integrate-and-fire neuron circuit implementing an integrate-and-fire operation includes: a first NPN device; a second NPN device connected in parallel to the first NPN device; a capacitor connected in parallel with the first NPN device and the second NPN device; and an output resistor connected in series to a cathode node of the second NPN element.

An anode terminal of the first NPN device may be connected in parallel to the capacitor and an anode terminal of the second NPN device, and a cathode end of the first NPN device may be connected to a ground, and the anode terminal of the second NPN device may be connected in parallel to the capacitor and the anode terminal of the first NPN device, and a cathode end of the second NPN device may be connected in parallel to the output resistor.

The first NPN device and the second NPN device may include: a first N-type semiconductor; a P-type semiconductor whose one end is heterogeneously bonded to one end of the first N-type semiconductor; a second N-type semiconductor whose one end is heterogeneously bonded to the other end of the P-type semiconductor; a control gate formed on top of the P-type semiconductor; an anode contacting the first N-type semiconductor through an ohmic junction; a cathode contacting the second N-type semiconductor through the ohmic junction; and the first N-type semiconductor and the second N-type semiconductor may have a relatively higher concentration than the P-type semiconductor, and the P-type semiconductor may have a smaller band gap than the first N-type semiconductor and the second N-type semiconductor.

According to another embodiment of the present invention, an operation method of an integrate-and-fire neuron circuit includes: integrating a synaptic current signal input to the first capacitor to increase potentials of the anode terminal of the first NPN device and the anode terminal of the second NPN device; converting the first NPN device and the second NPN device into a low-resistance state (LRS) by allowing a voltage of the first capacitor to reach a latch-up voltage of the first NPN device and the second NPN device; reducing the voltage of the first capacitor by discharging charge charged in the first capacitor through the first NPN device and the second NPN device converted into the low-resistance state (LRS); firing a spike by increasing a voltage of the second capacitor by the second NPN device converted into the low-resistance state (LRS); converting the second NPN device into a high-resistance state (HRS) at the voltage of the first capacitor greater than that of the first NPN device due to an increase in a voltage of the second capacitor so that charge is no longer charged in the second capacitor; initializing the second capacitor by allowing the charge of the second capacitor to flow out through the MOS transistor and reducing the voltage of the second capacitor to 0V; and initializing the first capacitor by reducing the voltage of the first capacitor to a latch-down voltage which is a voltage at which both the first NPN device and the second NPN device are converted into the high-resistance state (HRS).

The synaptic current may be input to an input node where the first capacitor, the anode terminal of the first NPN device, and the anode terminal of the second NPN device may be connected in parallel, and when the voltage of the first capacitor reaches the latch-up voltage of the first NPN device and the second NPN device by the synaptic current, the spike fire and initialization operations may be performed through the second capacitor and the MOS transistor.

When the same gate voltage is applied to the first NPN device and the second NPN device, the first NPN device and the second NPN device may have the same latch-up voltage, the first NPN device and the second NPN device may maintain the high-resistance state (HRS) before the voltage of the first capacitor reaches the latch-up voltage of the first NPN device and the second NPN device, and the input synaptic current may be charged in the first capacitor to perform an integration operation.

The first NPN device and the second NPN device may maintain the high-resistance state (HRS) by allowing only a few electrons of the high-concentration first N-type semiconductor to flow into the anode beyond a P-type semiconductor due to a high energy barrier of a PN+ junction.

When the voltage of the first capacitor reaches the latch-up voltage of the first NPN device and the second NPN device, the first NPN device and the second NPN device may be converted from the high-resistance state (HRS) into the low-resistance state (LRS), and the voltage of the first capacitor may decrease due to discharging of charge and the voltage of the second capacitor may increase due to charging of charge to fire the spike.

The first NPN device and the second NPN device may generate stored holes by high-level impact ionization by allowing electrons from the high-concentration first N-type semiconductor to flow into the anode beyond the P-type semiconductor, and the stored holes may be converted into the low-resistance state (LRS) indicating a high current by repeating a feedback loop operation that lowers the PN+ barrier to supply more source electrons.

The second NPN device may be converted into the high-resistance state (HRS) at the voltage of the first capacitor greater than that of the first NPN device due to the increase in the voltage of the second capacitor so that the charge is no longer charged in the second capacitor.

In the NPN device, the second capacitor may be initialized by allowing the charge of the second capacitor to flow out through the MOS transistor to which the gate voltage is applied and reducing the voltage of the second capacitor to 0V.

The first capacitor may be initialized by reducing the voltage of the first capacitor to the latch-down voltage which is the voltage at which both the first NPN device and the second NPN device are converted into the high-resistance state (HRS) by the first NPN device in the low-resistance state (LRS).

The first NPN device and the second NPN device may be re-converted into the high-resistance state (HRS) indicating a low current by a negative feedback loop in which the PN+ barrier increases again due to a recombination of the stored holes and a decrease in an impact ionization size.

The spike fire may have a fire frequency and height adjusted by regulating a gate voltage of the second NPN device, and may have the fire frequency adjusted according to a magnitude of the input synaptic current and an interval between pulses of the synaptic current.

When the same gate voltage is applied to the first NPN device and the second NPN device, an initialization operation of the first capacitor may be performed due to the first NPN device, and a spike fire operation may be performed due to the second NPN device, and the synaptic current may be charged in the first capacitor before the spike fire operation due to the second NPN device is performed to implement an excitatory post-synaptic potential (EPSP) in which the voltage of the first capacitor increases.

When a gate voltage greater than that of the second NPN device is applied to the first NPN device, the first NPN device may be converted into the low-resistance state (LRS) at a voltage lower than that of the first capacitor at which the spike fire due to the second NPN device occurs, and an inhibitory post-synaptic potential (IPSP) may be implemented in which the charge charged in the first capacitor flows out and the voltage of the first capacitor decreases.

The P-type semiconductor of the first NPN device and the second NPN device may be made of a material having a smaller band gap than the high-concentration first N-type semiconductor and second N-type semiconductor to have high charge mobility and an impact ionization coefficient, and thus, a latch-up phenomenon may occur at a small voltage due to a feedback loop, so the first NPN device and the second NPN device are converted into the LRS in which a high driving current flows.

An energy band offset formed in a double PN junction of the first NPN device and the second NPN device may inhibit an increase in a PN junction barrier due to a recombination of charges, so a magnitude of a driving current remains constant before latch-down, and the first NPN device and the second NPN device may form a hysteresis of a high driving current even at a small voltage to implement a stable initialization operation and reduce energy consumption.

According to another embodiment of the present invention, an operation method of an integrate-and-fire neuron circuit includes: integrating a synaptic current signal input to the capacitor to increase potentials of the anode terminal of the first NPN device and the anode terminal of the second NPN device; converting the first NPN device and the second NPN device into a low-resistance state (LRS) by allowing a voltage of the capacitor to reach a latch-up voltage of the first NPN device and the second NPN device; reducing the voltage of the capacitor by discharging charge charged in the capacitor through the first NPN device and the second NPN device converted into the low-resistance state (LRS); firing a spike by increasing a voltage of the output resistor by the second NPN device converted into the low-resistance state (LRS); converting the second NPN device into a high-resistance state (HRS) at the voltage of the capacitor greater than that of the first NPN device due to an increase in a voltage of the output resistor; initializing the output resistor by rapidly decreasing the voltage of the output resistor due to the second NPN element converted into the high resistance state (HRS); and initializing the capacitor by reducing the voltage of the capacitor to a latch-down voltage which is a voltage at which both the first NPN device and the second NPN device are converted into the high-resistance state (HRS).

The synaptic current may be input to an input node where the capacitor, the anode terminal of the first NPN device, and the anode terminal of the second NPN device may be connected in parallel, and when the voltage of the capacitor reaches the latch-up voltage of the first NPN device and the second NPN device by the synaptic current, the spike fire and initialization operations may be performed through the output resistor.

When the same gate voltage is applied to the first NPN device and the second NPN device, the first NPN device and the second NPN device may have the same latch-up voltage, the first NPN device and the second NPN device may maintain the high-resistance state (HRS) before the voltage of the capacitor reaches the latch-up voltage of the first NPN device and the second NPN device, and the input synaptic current may be charged in the capacitor to perform an integration operation.

The first NPN device and the second NPN device may maintain the high-resistance state (HRS) by allowing only a few electrons of the high-concentration first N-type semiconductor to flow into the anode beyond a P-type semiconductor due to a high energy barrier of a PN+ junction.

When the voltage of the capacitor reaches the latch-up voltage of the first NPN device and the second NPN device, the first NPN device and the second NPN device may be converted from the high-resistance state (HRS) into the low-resistance state (LRS), and the voltage of the capacitor may decrease due to flowing out of charge and the voltage of the output resistor increases due to voltage distribution to fire the spike.

The first NPN device and the second NPN device may generate stored holes by high-level impact ionization by allowing electrons from the high-concentration first N-type semiconductor to flow into the anode beyond the P-type semiconductor, and the stored holes may be converted into the low-resistance state (LRS) indicating a high current by repeating a feedback loop operation that lowers the PN+ barrier to supply more source electrons.

The second NPN device may be converted into the high-resistance state (HRS) at the voltage of the capacitor greater than that of the first NPN device due to the increase in the voltage of the output resistor.

In the second NPN device, the voltage of the output resistor may be initialized by decreasing due to the first NPN device converted into the high resistance state (HRS).

The capacitor may be initialized by decreasing the voltage of the capacitor to the latch-down voltage which is the voltage at which both the first NPN device and the second NPN device are converted into the high-resistance state (HRS) by the first NPN device in the low-resistance state (LRS).

The first NPN device and the second NPN device may be re-converted into the high-resistance state (HRS) indicating a low current by a negative feedback loop in which the PN+ barrier increases again due to a recombination of the stored holes and a decrease in an impact ionization size.

The spike fire may have a fire frequency and height adjusted by regulating a gate voltage of the second NPN device, and may have the fire frequency adjusted according to a magnitude of the input synaptic current and an interval between pulses of the synaptic current.

When the same gate voltage is applied to the first NPN device and the second NPN device, an initialization operation of the capacitor may be performed due to the first NPN device, and a spike fire operation may be performed due to the second NPN device, and the synaptic current may be charged in the capacitor before the spike fire operation due to the second NPN device is performed to implement an excitatory post-synaptic potential (EPSP) in which the voltage of the capacitor increases.

When a gate voltage greater than that of the second NPN device is applied to the first NPN device, the first NPN device may be converted into the low-resistance state (LRS) at a voltage lower than that of the capacitor at which the spike fire due to the second NPN device occurs, and an inhibitory post-synaptic potential (IPSP) may be implemented in which the charge charged in the capacitor flows out and the voltage of the capacitor decreases.

When the gate voltage greater than that of the second NPN device is applied to the first NPN device, as the gate voltage applied to the first NPN device increases, the strong inhibitory post-synaptic potential (IPSP) may be realized in which the charge charged in the capacitor flows out more and the voltage of the capacitor decreases more.

The P-type semiconductor of the first NPN device and the second NPN device may be made of a material having a smaller band gap than the high-concentration first N-type semiconductor and second N-type semiconductor to have high charge mobility and an impact ionization coefficient, and thus, a latch-up phenomenon may occur at a small voltage due to a feedback loop, so the first NPN device and the second NPN device are converted into the LRS in which a high driving current flows.

An energy band offset formed in a double PN junction of the first NPN device and the second NPN device may inhibit an increase in a PN junction barrier due to a recombination of charges, so a magnitude of a driving current remains constant before latch-down, and the first NPN device and the second NPN device may form a hysteresis of a high driving current even at a small voltage to implement a stable initialization operation and reduce energy consumption.

### BRIEF DESCRIPTION OF DRAWINGS

FIG. 1 is a schematic diagram of an integrate-and-fire neuron circuit according to an embodiment of the present invention.

FIG. 2 is a schematic diagram of a heterojunction NPN device of the integrate-and-fire neuron circuit according to the embodiment of the present invention.

FIG. 3 is a schematic diagram of an n-type MOS transistor device of the integrate-and-fire neuron circuit according to the embodiment of the present invention.

FIGS. 4 to 6 are energy diagrams of the NPN device of the integrate-and-fire neuron circuit according to an embodiment of the present invention according to various anode voltages.

FIG. 7 is an anode current-anode voltage output curve of the NPN device of the integrate-and-fire neuron circuit according to the embodiment of the present invention.

FIG. 8 is a schematic diagram of an integrate-and-fire neuron circuit according to an embodiment of the present invention.

FIG. 9 is a schematic diagram of a heterojunction NPN device of the integrate-and-fire neuron circuit according to the embodiment of the present invention.

FIGS. 10 to 12 are energy diagrams of the NPN device of the integrate-and-fire neuron circuit according to an embodiment of the present invention according to various anode voltages.

FIG. 13 is an anode current-anode voltage output curve of the NPN device of the integrate-and-fire neuron circuit according to the embodiment of the present invention.

FIG. 14 is a flowchart for describing a process of an operation method of an integrate-and-fire neuron circuit according to the present invention.

FIGS. 15 to 17 are diagrams for describing an integrate-and-fire operation mechanism of the integrate-and-fire neuron circuit according to the embodiment of the present invention.

FIG. 18 is a timing diagram of the integrate-and-fire operation of the integrate-and-fire neuron circuit according to the embodiment of the present invention.

FIG. 19 is a timing diagram of the integrate-and-fire operation according to various synaptic current magnitudes of the integrate-and-fire neuron circuit according to the embodiment of the present invention.

FIG. 20 is a timing diagram of the integrate-and-fire operation according to an interval between pulses of various synaptic current magnitudes in the integrate-and-fire neuron circuit according to the embodiment of the present invention.

FIG. 21 is an anode current-anode voltage output curve according to various gate voltages of the NPN device of the integrate-and-fire neuron circuit according to the embodiment of the present invention.

FIG. 22 is a timing diagram of the integrate-and-fire operation according to the gate voltage of the integrate-and-fire neuron circuit according to the embodiment of the present invention.

FIG. 23 is a diagram for describing the mechanism by which an inhibitory post-synaptic potential (IPSP) is generated in the integrate-and-fire neuron circuit according to the embodiment of the present invention.

FIG. 24 is a timing diagram of an operation in which an excitatory post-synaptic potential (EPSP) and the inhibitory post-synaptic potential (IPSP) are summed when a synaptic inhibitory signal is input to the integrate-and-fire neuron circuit according to the embodiment of the present invention.

FIG. 25 is a flowchart for describing a process of an operation method of an integrate-and-fire neuron circuit according to the present invention.

FIGS. 26 to 28 are diagrams for describing an integrate-and-fire operation mechanism of the integrate-and-fire neuron circuit according to the embodiment of the present invention.

FIG. 29 is a timing diagram of the integrate-and-fire operation of the integrate-and-fire neuron circuit according to the embodiment of the present invention.

FIG. 30 is a timing diagram of the integrate-and-fire operation according to various synaptic current magnitudes of the integrate-and-fire neuron circuit according to the embodiment of the present invention.

FIG. 31 is a timing diagram of the integrate-and-fire operation according to an interval between pulses of various synaptic current magnitudes in the integrate-and-fire neuron circuit according to the embodiment of the present invention.

FIG. 32 is an anode current-anode voltage output curve according to various gate voltages of the NPN device of the integrate-and-fire neuron circuit according to the embodiment of the present invention.

FIG. 33 is a timing diagram of the integrate-and-fire operation according to the gate voltage of the integrate-and-fire neuron circuit according to the embodiment of the present invention.

FIG. 34 is a diagram for describing the mechanism by which an inhibitory post-synaptic potential (IPSP) is generated in the integrate-and-fire neuron circuit according to the embodiment of the present invention.

FIG. 35 is a timing diagram of an operation in which an excitatory post-synaptic potential (EPSP) and the inhibitory post-synaptic potential (IPSP) are summed when a synaptic inhibitory signal is input to the integrate-and-fire neuron circuit according to the embodiment of the present invention.

FIG. 36 is a timing diagram of the operation of summing the excitatory post-synaptic potential (EPSP) and the inhibitory post-synaptic potential (IPSP) when a larger synaptic inhibitory signal is input to the integrate-and-fire neuron circuit according to an embodiment of the present invention.

### DETAILED DESCRIPTION

The present invention may be variously modified and have several exemplary embodiments. Therefore, specific exemplary embodiments of the present invention will be illustrated in the accompanying drawings and be described in detail herein. However, the present invention is not limited to a specific disclosed form, but includes all modifications, equivalents, and substitutions without departing from the scope and spirit of the present invention.

Unless indicated otherwise, it is to be understood that all the terms used in the specification including technical and scientific terms have the same meaning as those that are generally understood by those who skilled in the art. Terms generally used and defined by a dictionary should be interpreted as having the same meanings as meanings within a context of the related art and should not be interpreted as having ideal or excessively formal meanings unless being clearly defined otherwise in the present specification.

In addition, in this specification, terms such as an anode, a base, a cathode, a control gate, an N-type region, a P-type region, a PN junction, a heterojunction an ohmic junction, and an integrate-and-fire operation are interpreted at a level that can be understood by those skilled in the art to which the present invention pertains, and their types may also be changed in various ways, all of which fall within the scope of the present invention. In addition, a semiconductor layer is a device layer containing a semiconductor material and is not limited to a horizontal or vertical shape, and any and all semiconductor structures that include at least one NPN or PNP junction correspond thereto. In addition, a control gate is described as being positioned on the semiconductor layer, but it is not limited to types such as a bottom or gate-all around type, and all control gate structures in contact with the semiconductor layer correspond thereto. It will be understood that when an element such as a layer, a region, or a substrate is referred to as being “on” another element, it may be present directly on other elements or there may be intermediate elements therebetween.

Although the terms first, second, etc. may be used to describe various elements, components, regions, layers and/or areas, these elements, components, regions, layers, and/or areas should not be limited to these terms and it will be understood that the above terms are used only for the purpose of distinguishing one component from another.

Hereinafter, exemplary embodiments of the present invention will be described in detail with reference to the accompanying drawings.

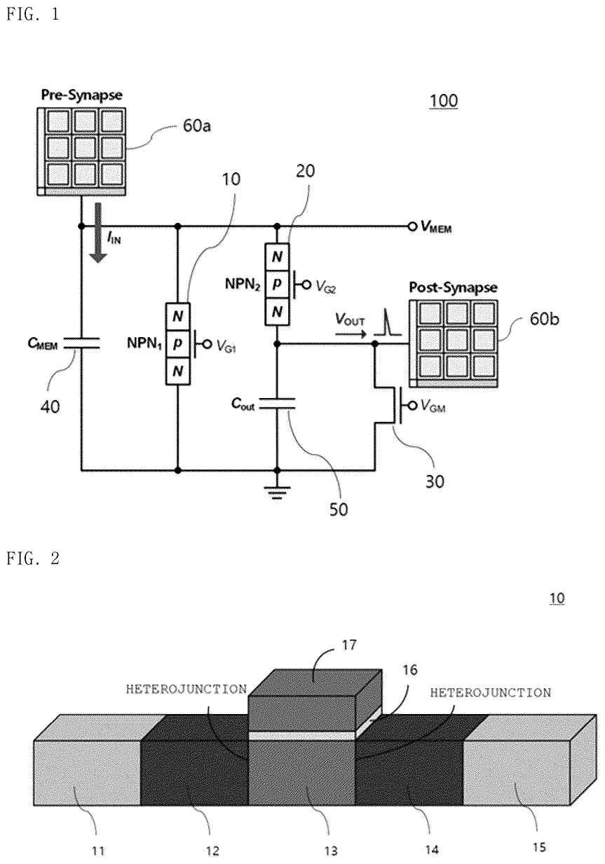

FIG. 1 is a schematic diagram of an integrate-and-fire neuron circuit according to an embodiment of the present invention.

Referring to FIG. 1, an integrate-and-fire neuron circuit 100 according to an embodiment of the present invention is configured to include first and second NPN devices 10 and 20, which are NPN devices having the same structure that integrates a synaptic signal, a MOS transistor 30, a first capacitor 40 that is a membrane capacitor C_{MEM} that integrates a synaptic current signal, and a second capacitor 50 that is an out capacitor Cₒᵤₜ that fires and resets a spike.

The first capacitor 40 is 22 pF and the second capacitor 50 is 10 pF. The first capacitor 40, the first NPN device 10, and the second NPN device 20 are connected in parallel. An anode voltage of the first NPN device 10 and the second NPN device 20 are the same as a membrane voltage of a neuron. Synapses are connected to both ends of the integrate-and-fire neuron circuit 100. A synapse 60a connected to a front end converts a spike received from a pre-synaptic neuron into a current having a size reflecting a weight, and this synaptic current signal I_{IN} is input to a node where the first NPN device 10, the second NPN device 20, and the first capacitor 40 are connected in parallel.

A cathode of the first NPN device 10 is connected to a ground, and the second capacitor 50 and the MOS transistor 30 are connected in parallel to a cathode node of the second NPN device 20. The first NPN device 10 and the second NPN device 20 having the same structure exhibit a bistable resistance state due to a feedback phenomenon, and the above characteristics play a major role in performing the integrate-and-fire operation of the neuron circuit. A synapse 60b at a rear end is connected to the cathode node of the second NPN device 20 and receives a spike fired by the neuron circuit.

FIG. 2 is a schematic diagram of a heterojunction NPN device of the integrate-and-fire neuron circuit according to the embodiment of the present invention.

Referring to FIG. 2, the first NPN device 10 of the integrate-and-fire neuron circuit according to an embodiment of the present invention is configured to include an anode 11, a first N-type semiconductor 12, a P-type semiconductor 13, a second N-type semiconductor 14, a cathode 15, an insulating film 16, and a control gate 17.

Both the anode 11 and the cathode 15 in contact with the NPN semiconductor layers 12, 13, and 14 form an ohmic junction, and the P-type semiconductor 13 is made of silicon germanium, and a control gate 17 is formed on the P-type semiconductor 13. In addition, an insulating film 16 may be positioned between the P-type semiconductor 13 and the control gate.

In the first NPN device 10 according to an embodiment of the present invention, high-concentration N-type silicon semiconductors 12 and 14 form a heterojunction with a P-type semiconductor 13 made of silicon germanium.

Since the silicon germanium, which is the material that makes up the P-type semiconductor 13, forms a hysteresis that allows a sufficiently large driving current to flow even at a low anode voltage level, the integrate-and-fire operation may be stably performed at a lower voltage than the NPN device with the P-type semiconductor layer made of silicon, thereby reducing the energy consumption of the entire circuit.

Since the second NPN device 20 has the same structure as the first NPN device 10, detailed description thereof will be omitted.

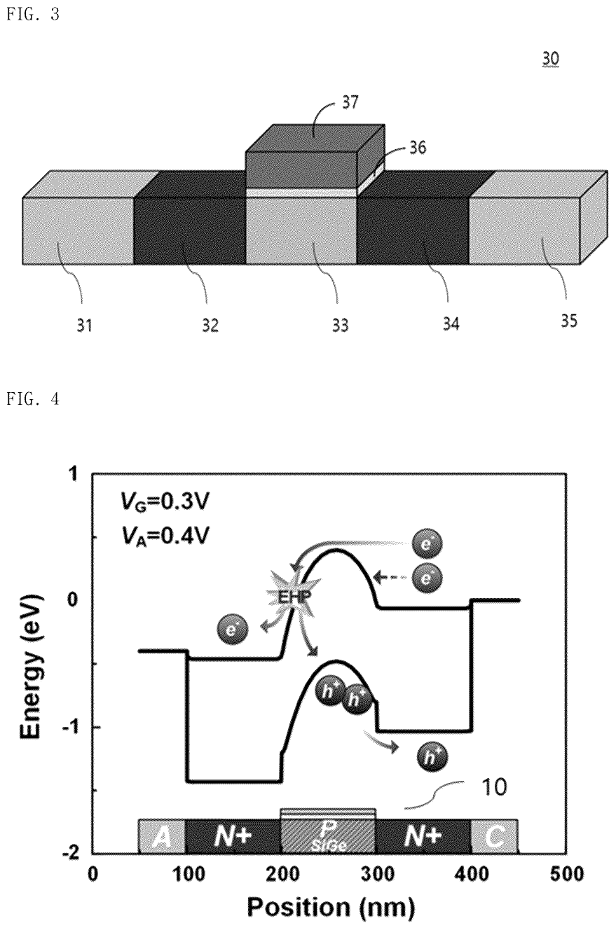

FIG. 3 is a schematic diagram of an n-type MOS transistor device of the integrate-and-fire neuron circuit according to the embodiment of the present invention.

Referring to FIG. 3, the N-type MOS transistor 30 of the integrate-and-fire neuron circuit according to an embodiment of the present invention is configured to include an anode 31, a first N-type semiconductor 32, a P-type semiconductor 33, a second N-type semiconductor 34, a cathode 35, an insulating film 36, and a control gate 37.

Both the anode 31 and the cathode 35 in contact with the semiconductor layer form an ohmic junction, and a control gate 37 is formed on the P-type semiconductor 33. In addition, the insulating film 36 may be positioned between the P-type semiconductor 33 and the control gate 37.

FIGS. 4 to 6 are energy diagrams of the NPN device of the integrate-and-fire neuron circuit according to an embodiment of the present invention according to various anode voltages. The NPN device illustrated in FIGS. 4 to 6 will be described using the first NPN device 10 illustrated in FIG. 2 as an example.

FIG. 4 illustrates an energy band diagram when a gate voltage V_{G} of 0.3V and an anode voltage V_{A} of 0.4V are applied to the first NPN device 10. Since a high energy barrier is formed by a PN⁺ junction, only a few electrons go beyond the P-type semiconductor 13 and encounter the high electric field of the junction of the highly concentrated first N-type semiconductor 12 and the P-type semiconductor 13, which are in contact with the anode 11, to generate electron-hole pairs due to the impact ionization effect.

In this case, the generated holes are integrated in the P-type semiconductor 13 to reduce the energy barrier of the PN⁺ junction, and more electrons from the high-concentration second N-type semiconductor 114 contacting the cathode 15 go beyond the P-type semiconductor 13 to be transferred the anode 11. However, since holes are not sufficiently integrated in the P-type semiconductor 13 and the high PN+ junction energy barrier is still formed, the device maintains a high-resistance state (HRS) indicating a low current.

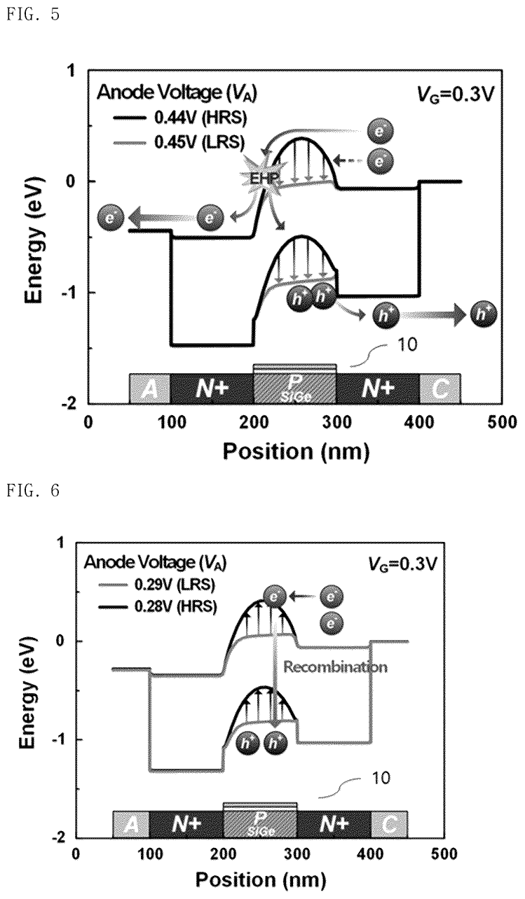

FIG. 5 illustrates the energy band when latch-up of the first NPN device 10 occurs.

Referring to FIG. 5, when the gate voltage V_{G} of 0.3V and the anode voltage V_{A} of 0.44V are applied to the first NPN device 10, the holes generated due to the impact ionization are sufficiently integrated in the P-type semiconductor 13, so the energy barrier of the PN⁺ junction is drastically lowered, and a low-resistance state (LRS) with high current is realized.

FIG. 6 illustrates the energy band when latch-down of the first NPN device 10 occurs.

Referring to FIG. 6, when the anode voltage V_{A} decreases and reaches 0.29V with the gate voltage V_{G} of 0.3V applied, the energy barrier of the PN⁺ junction rapidly increases due to the recombination of holes integrated in the P-type semiconductor and is converted into the HRS.

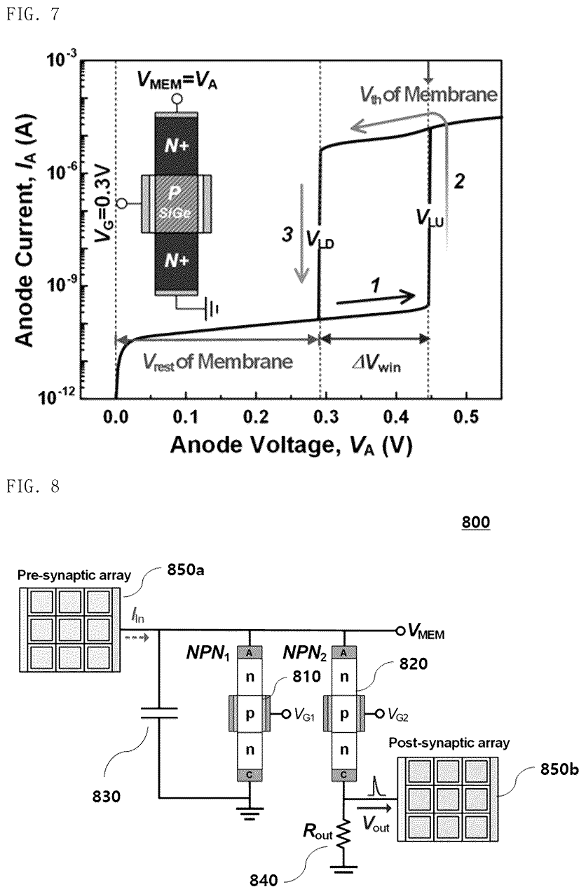

FIG. 7 is an anode current-anode voltage output curve of the NPN device of the integrate-and-fire neuron circuit according to the embodiment of the present invention.

When the anode voltage V_{A} increases from 0V to 0.55V, the NPN device is converted into the low-resistance state (LRS) at 0.44 V due to the formation of an electron-hole pair caused by the impact ionization, and conversely, when the anode voltage V_{A} decreases back to 0V, the NPN device is again converted into the high-resistance state (HRS) at 0.29V due to the recombination of the electron-hole pair.

FIG. 8 is a schematic diagram of an integrate-and-fire neuron circuit according to an embodiment of the present invention.

Referring to FIG. 8, an integrate-and-fire neuron circuit 800 according to an embodiment of the present invention is configured to include first and second NPN devices 810 and 820, which are NPN devices having the same structure that integrates a synaptic signal, a capacitor 830, which is a membrane capacitor C_{MEM} that integrates a synaptic current signal, and an output resistor 840 that fires and resets the spike.

The capacitor 830 is 4.7 pF. The capacitor 830, the first NPN device 810, and the second NPN device 820 are connected in parallel. An anode voltage of the first NPN device 810 and the second NPN device 820 are the same as a membrane voltage of a neuron. Synapses are connected to both ends of the integrate-and-fire neuron circuit 800. A synapse 850a connected to a front end converts a spike received from a pre-synaptic neuron into a current having a size reflecting a weight, and this synaptic current signal I_{IN} is input to a node where the first NPN device 810, the second NPN device 820, and the capacitor 830 are connected in parallel.

A cathode of the first NPN device 810 is connected to a ground, and the output resistor 840 is connected in parallel to a cathode node of the second NPN device 820. The first NPN device 810 and the second NPN device 820 having the same structure exhibit a bistable resistance state due to a feedback phenomenon, and the above characteristics play a major role in performing the integrate-and-fire operation of the neuron circuit. A synapse 850b at a rear end is connected to the cathode node of the second NPN device 820 and receives a spike fired by the neuron circuit.

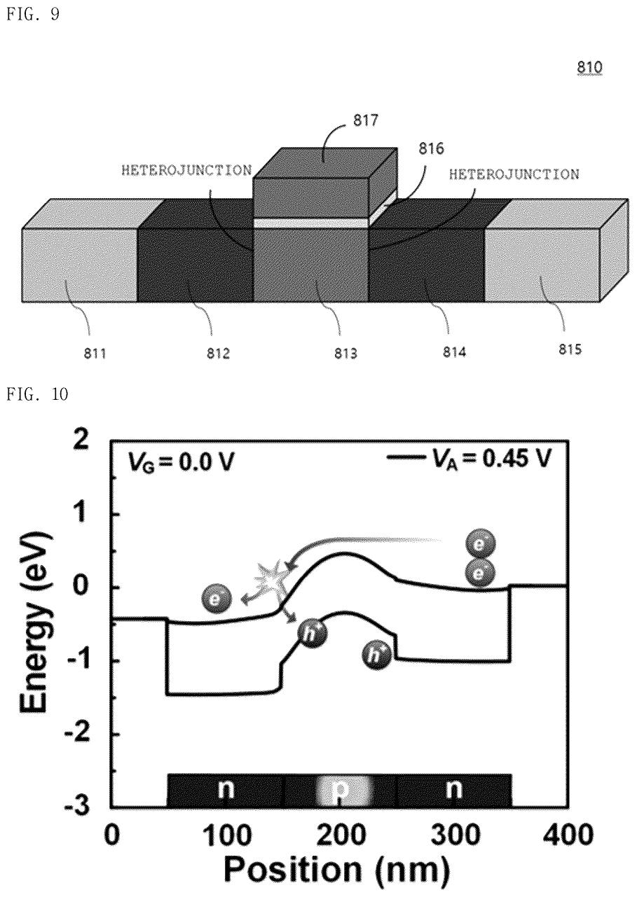

FIG. 9 is a schematic diagram of a heterojunction NPN device of the integrate-and-fire neuron circuit according to the embodiment of the present invention.

Referring to FIG. 9, the first NPN device 810 of the integrate-and-fire neuron circuit according to an embodiment of the present invention is configured to include an anode 811, a first N-type semiconductor 812, a P-type semiconductor 813, a second N-type semiconductor 814, a cathode 815, an insulating film 816, and a control gate 817.

Both the anode 811 and the cathode 815 in contact with the NPN semiconductor layers 812, 813, and 814 form an ohmic junction, and the P-type semiconductor 813 is made of silicon germanium, and a control gate 817 is formed on the P-type semiconductor 813. In addition, an insulating film 816 may be positioned between the P-type semiconductor 813 and the control gate.

In the first NPN device 810 according to an embodiment of the present invention, high-concentration N-type silicon semiconductors 812 and 814 form a heterojunction with a P-type semiconductor 813 made of silicon germanium.

Since the silicon germanium, which is the material that makes up the P-type semiconductor 813, forms a hysteresis that allows a sufficiently large driving current to flow even at a low anode voltage level, the integrate-and-fire operation may be stably performed at a lower voltage than the NPN device with the P-type semiconductor layer made of silicon, thereby reducing the energy consumption of the entire circuit.

Since the second NPN device 820 has the same structure as the first NPN device 810, detailed description thereof will be omitted.

FIGS. 10 to 12 are energy diagrams of the NPN device of the integrate-and-fire neuron circuit according to an embodiment of the present invention according to various anode voltages. The NPN device illustrated in FIGS. 10 to 12 will be described using the first NPN device 10 illustrated in FIG. 9 as an example.

FIG. 10 illustrates an energy band diagram when a gate voltage V_{G} of 0.0V and an anode voltage V_{A} of 0.4V are applied to the first NPN device 810. Since a high energy barrier is formed by a PN⁺ junction, only a few electrons go beyond the P-type semiconductor 813 and encounter the high electric field of the junction of the highly concentrated first N-type semiconductor 812 and the P-type semiconductor 813, which are in contact with the anode 811, to generate electron-hole pairs due to the impact ionization effect.

In this case, the generated holes are integrated in the P-type semiconductor 813 to reduce the energy barrier of the PN⁺ junction, and more electrons from the high-concentration second N-type semiconductor 814 contacting the cathode 815 go beyond the P-type semiconductor 813 to be transferred the anode 811. However, since holes are not sufficiently integrated in the P-type semiconductor 813 and the high PN+ junction energy barrier is still formed, the device maintains a high-resistance state (HRS) indicating a low current.

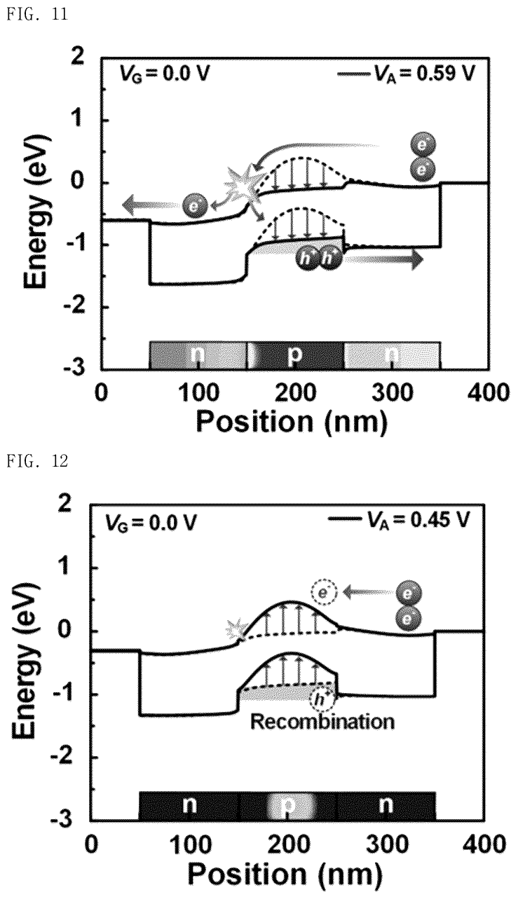

FIG. 11 illustrates the energy band when latch-up of the first NPN device 810 occurs.

Referring to FIG. 11, when the gate voltage V_{G} of 0.0V and the anode voltage V_{A} of 0.59V are applied to the first NPN device 810, the holes generated due to the impact ionization are sufficiently integrated in the P-type semiconductor 813, so the energy barrier of the PN⁺ junction is drastically lowered, and a low-resistance state (LRS) with high current is realized.

FIG. 12 illustrates the energy band when latch-down of the first NPN device 810 occurs.

Referring to FIG. 12, when the anode voltage V_{A} decreases and reaches 0.0V with the gate voltage V_{G} of 0.30V applied, the energy barrier of the PN⁺ junction rapidly increases due to the recombination of holes integrated in the P-type semiconductor and is converted into the HRS.

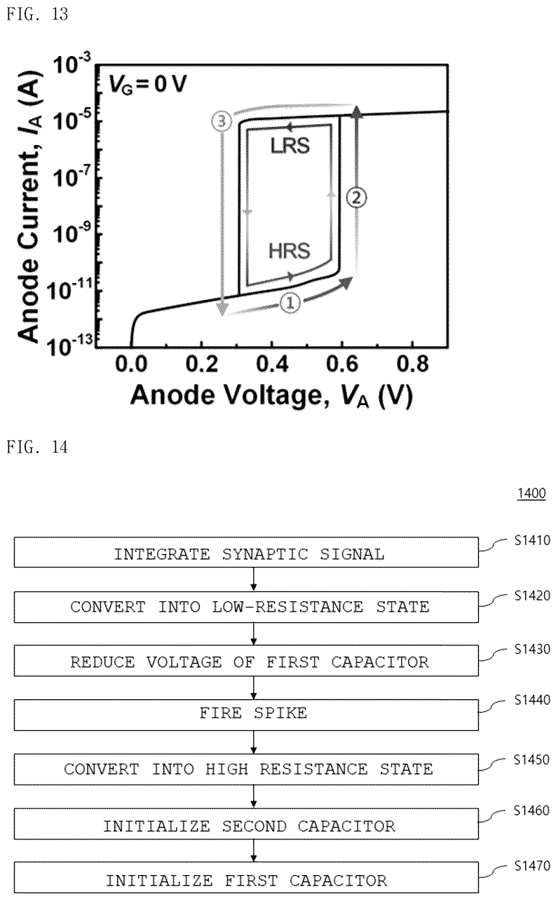

FIG. 13 is an anode current-anode voltage output curve of the NPN device of the integrate-and-fire neuron circuit according to the embodiment of the present invention.

When the anode voltage V_{A} increases from 0V to 0.9V, the NPN device is converted into the low-resistance state (LRS) at 0.59V due to the formation of an electron-hole pair caused by the impact ionization, and conversely, when the anode voltage V_{A} decreases back to 0V, the NPN device is again converted into the high-resistance state (HRS) at 0.30V due to the recombination of the electron-hole pair.

FIG. 14 is a flowchart for describing a process of an operation method of an integrate-and-fire neuron circuit according to the present invention.

As illustrated in FIG. 14, the operation method of the integrate-and-fire neuron circuit according to the present invention includes a synaptic signal integration step (S1410), a low-resistance state conversion step (S1420), and a first capacitor voltage reduction step (S1430), a spike firing step (S1440), a high-resistance state conversion step (S1450), a second capacitor initialization step (S1460), and a first capacitor initialization step (S1470).

In the synaptic signal integration step (S1410), the synaptic current signal input to the first capacitor is integrated to increase the potentials of the anode terminal of the first NPN device and the anode terminal of the second NPN device.

In the low-resistance state conversion step (S1420), the voltage of the first capacitor reaches the latch-up voltage of the first NPN device and the second NPN device, so the first NPN device and the second NPN device are converted into the low-resistance state (LRS).

In the first capacitor voltage reduction step (S1430), the charge charged in the first capacitor is discharged through the first NPN device and the second NPN device converted into the low-resistance state (LRS) to reduce the voltage of the first capacitor.

In the spike firing step (S1440), the voltage of the second capacitor increases by the second NPN device converted into the low-resistance state (LRS) to fire the spike.

In the high-resistance state conversion step (S1450), the second NPN device is converted into the high-resistance state (HRS) at the voltage of the first capacitor greater than that of the first NPN device due to the increase in the voltage of the second capacitor, so charge is no longer charged in the second capacitor.

In the second capacitor initialization step (S1460), the second capacitor is initialized by allowing the charge of the second capacitor to flow out through the MOS transistor and reducing the voltage of the second capacitor to 0V.

In the first capacitor initialization step (S1470), the first capacitor is initialized by reducing the voltage of the first capacitor to a latch-down voltage which is a voltage at which both the first NPN device and the second NPN device are converted into the high-resistance state (HRS).

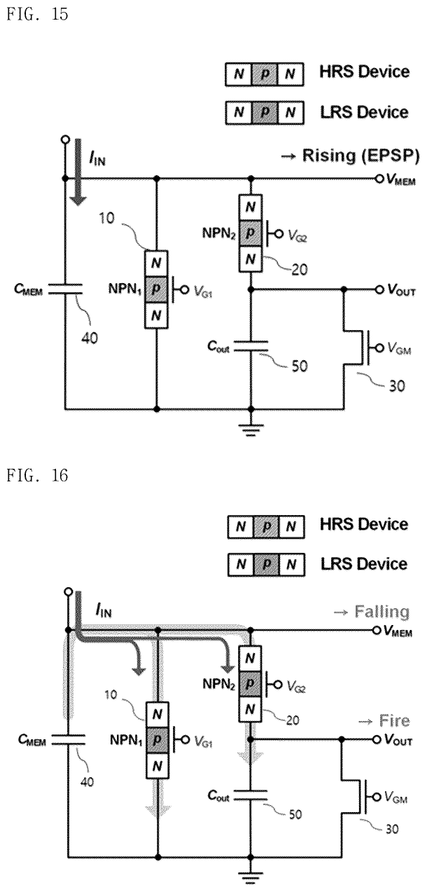

FIGS. 15 to 17 are diagrams for describing an integrate-and-fire operation mechanism of the integrate-and-fire neuron circuit according to the embodiment of the present invention.

FIG. 15 is a diagram illustrating an integration operation mechanism of the integrate-and-fire neuron circuit according to the embodiment of the present invention.

The synaptic current signal I_{IN} is input to the node where the first NPN device 10, the second NPN device 20, and the first capacitor 40 are connected in parallel. The integrate-and-fire operation is achieved by applying the same gate voltage V_{G1}=V_{G2} to the first NPN device 10 and the second NPN device 20, and a latch-up phenomenon occurs where the conversion into the low-resistance state (LRS) occurs at the same magnitude of membrane voltage V_{MEM}. The first NPN device 10 and the second NPN device 20 maintain the high-resistance state (HRS) before the membrane voltage V_{MEM} reaches a latch-up voltage V_{LU} of the first NPN device 10 and the second NPN device 20.

Therefore, when the membrane voltage V_{MEM}<latch-up voltage V_{LU}, the synaptic current signal I_{IN} hardly flows into the first NPN device 10 and the second NPN device 20 in the high-resistance state (HRS), and is mostly charged and integrated in the first capacitor 40 connected in parallel. While the synaptic current signal I_{IN} is input, the membrane voltage V_{MEM} increases over time until it reaches the latch-up voltage V_{LU}.

FIG. 16 is a diagram illustrating a fire operation mechanism of the integrate-and-fire neuron circuit according to the embodiment of the present invention.

The firing operation occurs when the membrane voltage V_{MEM} reaches the latch-up voltage V_{LU} and the first NPN device 10 and the second NPN device 20 are simultaneously converted into the low-resistance state (LRS). The membrane voltage V_{MEM} begins to decrease as the charge integrated in the first capacitor 40, which is the membrane capacitor, flows out through the first NPN device 10 and the second NPN device 20 converted into the low-resistance state (LRS).

At the same time, the charge flowing out through the second NPN device 20 is charged in the second capacitor 50, so an output voltage Vₒᵤₜ rapidly increases to fire the spike. While the membrane voltage V_{MEM} decreases, a voltage V_{AC} applied across the second NPN device 20 becomes smaller than that of the first NPN device 10 due to the increasing output voltage Vₒᵤₜ. Therefore, the second NPN device 20 is converted into the high-resistance state (HRS) at the membrane voltage V_{MEM} greater than that of the first NPN device 10, so charge is no longer charged in the second capacitor 50.

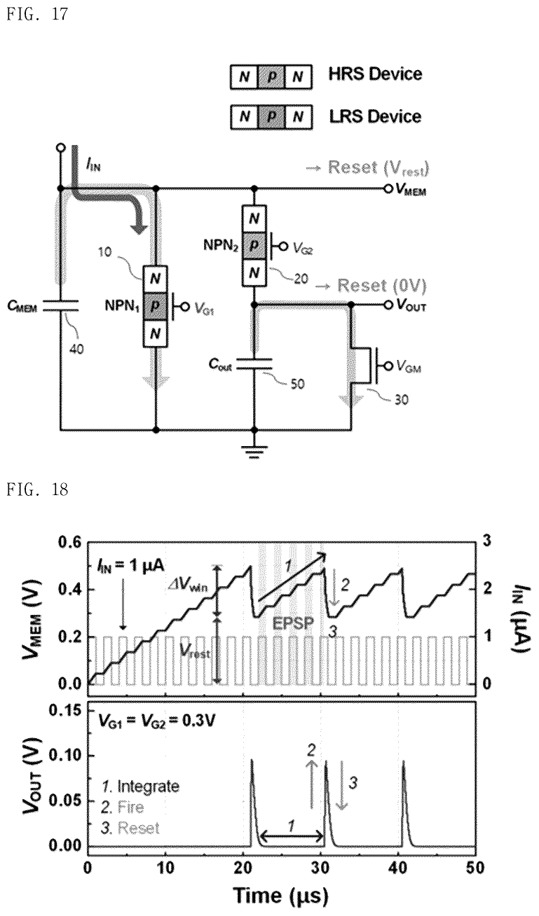

FIG. 17 is a diagram illustrating an initialization operation mechanism of the integrate-and-fire neuron circuit according to the embodiment of the present invention.

The second capacitor is initialized by allowing the charge of the second capacitor 50 to flow out through the MOS transistor 30 to which the gate voltage V_{GM} is applied and reducing the output voltage Vₒᵤₜ to 0V. Meanwhile, the second capacitor is initialized by reducing the membrane voltage V_{MEM} to the latch-down voltage V_{LD} which is the voltage at which both the first NPN device 10 and the second NPN device 20 are converted into the high-resistance state (HRS) by the first NPN device in the low-resistance state (LRS).

FIG. 18 is a timing diagram of the integrate-and-fire operation of the integrate-and-fire neuron circuit according to the embodiment of the present invention. In the embodiment illustrated in FIG. 17, when the synaptic current signal I_{IN} having a magnitude of 1 μA is input to the integrate-and-fire neuron circuit 100 according to an embodiment at intervals of 1 μs, the timing of the integrate-and-fire operation is illustrated.

The fire-and-integrate operation is achieved by applying the same gate voltage to the first NPN device 10 and the second NPN device 20. When the membrane voltage V_{MEM}<latch-up voltage V_{LU}, both the first NPN device 10 and the second NPN device 20 maintain the high-resistance state (HRS), so the synaptic current signal I_{IN} may charge the first capacitor 40. In this way, while the synaptic current signal I_{IN} is input, an excitatory post-synaptic potential increasing until the membrane voltage V_{MEM} reaches the latch-up voltage V_{LU} is achieved. Here, the excitatory post-synaptic potential (EPSP) refers to the phenomenon in which a membrane potential of a neuron increases due to an excitatory signal from a synapse and approaches a threshold.

The membrane voltage V_{MEM} begins to decrease at the latch-up voltage V_{LU} at which the first NPN device 10 and the second NPN device 20 are converted into the low-resistance state (LRS), and decreases to the latch-down voltage V_{LD} where the first NPN device 10 and the second NPN device 20 are converted into the high-resistance state (HRS).

Comparing with the anode current-anode voltage output curve of FIG. 7, it can be seen that a difference between a threshold voltage Vₜₕ and a rest voltage Vᵣₑₛₜ of a neuron is equal to a width ΔV_{win} of hysteresis of the NPN device according to one embodiment.

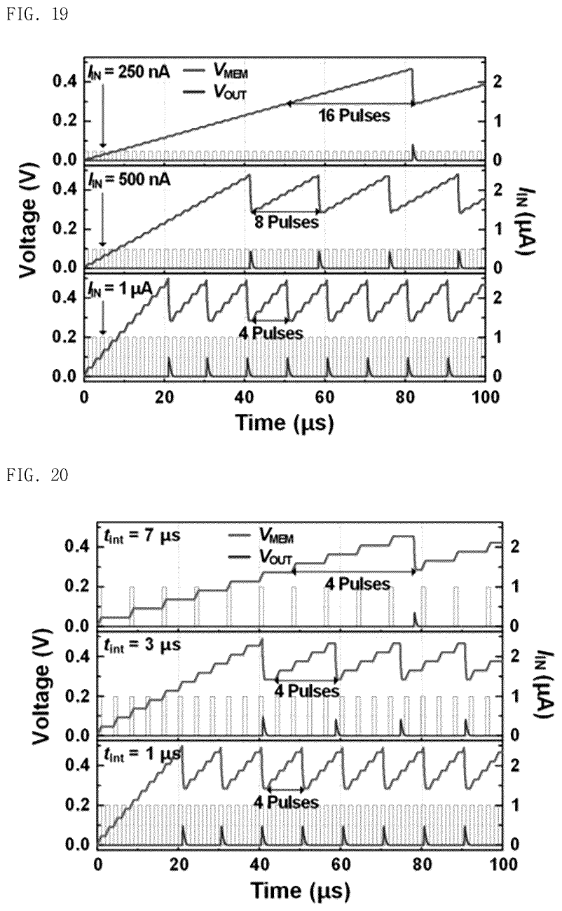

FIG. 19 is a timing diagram of the integrate-and-fire operation according to various synaptic current magnitudes of the integrate-and-fire neuron circuit according to the embodiment of the present invention. In the embodiment illustrated in FIG. 18, when a current pulse having a width of 1 μs is input 50 times intervals of 1 μs for 100 μs by adjusting the magnitude of the synaptic current signal I_{IN}, the timing of the integrate-and-fire operation of the neuron circuit according to one embodiment is illustrated.

The magnitude of the synaptic current signal I_{IN} is proportional to the size of the weight stored in the synapse. Referring to FIG. 18, it can be seen that as the size of the synaptic current signal I_{IN} increases, the number of current pulses required to reach the threshold voltage Vₜₕ from the rest voltage Vᵣₑₛₜ decreases, and thus the fire frequency increases.

FIG. 20 is a timing diagram of the integrate-and-fire operation according to an interval between pulses of various synaptic current magnitudes in the integrate-and-fire neuron circuit according to the embodiment of the present invention. In the embodiment illustrated in FIG. 19, when a current pulse having a width of 1 μs is input at a certain magnitude of 1 μA for 100 μs by adjusting a size of an interval tᵢₙₜ between the synaptic current pulses, the timing of the integrate-and-fire operation of the neuron circuit according to one embodiment is illustrated.

Since the synaptic current signal I_{IN} is input when the synapse receives a spike from the pre-synaptic neuron, the interval tᵢₙₜ between the synaptic current pulses is inversely proportional to the fire frequency of the pre-synaptic neuron. As the size of the interval tᵢₙₜ between the synaptic current pulses decreases, the time required to reach the threshold voltage Vₜₕ from the rest voltage Vᵣₑₛₜ decreases, so the fire frequency increases.

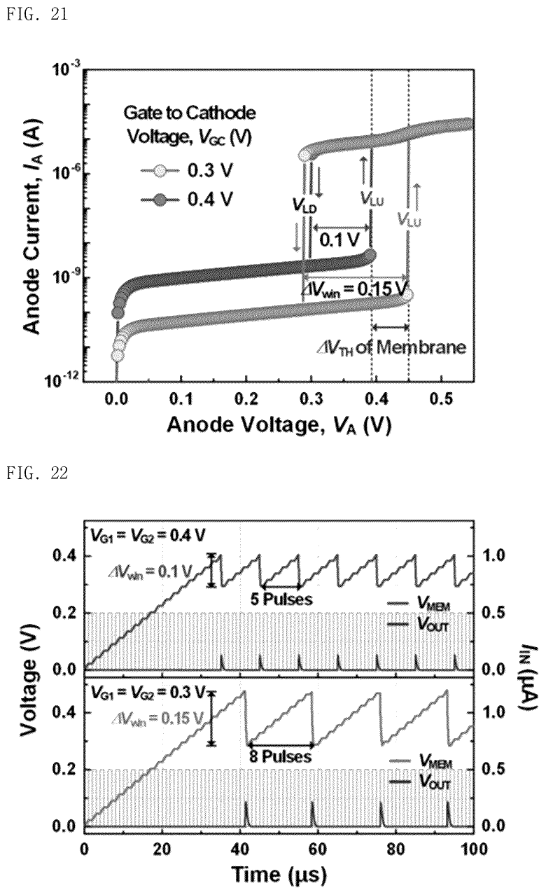

FIG. 21 is an anode current-anode voltage output curve according to various gate voltages of the NPN device of the integrate-and-fire neuron circuit according to the embodiment of the present invention. In the embodiment illustrated in FIG. 20, a gate-cathode voltage V_{GC} was tested by varying between 0.3V and 0.4V.

As the gate voltage V_{G} applied to the NPN device increases, the energy barrier of the PN⁺ junction is lowered, so electrons from the high-concentration N-type semiconductor N⁺ easily flow into the anode beyond the P-type semiconductor. Therefore, as the gate voltage V_{G} increases, the NPN device is converted into the low-resistance state (LRS) by a feedback loop at a lower voltage. When the same gate voltage V_{G} of 0.4V is applied to the first NPN device 10 and the second NPN device 20, a width ΔV_{win} of hysteresis decreased by 0.05V compared to when the same gate voltage V_{G} of 0.3V is applied.

FIG. 22 is a timing diagram of the integrate-and-fire operation according to the gate voltage of the integrate-and-fire neuron circuit according to the embodiment of the present invention. In the embodiment illustrated in FIG. 21, the timing of the integrate-and-fire operation when a current pulse having a magnitude of 500 nA and a width of 1 μs is input 50 times for 100 μs under the conditions of V_{G1}=V_{G2}=0.3V and 0.4V is illustrated.

As the width ΔV_{win} of hysteresis becomes smaller, the number of current pulses required to reach the threshold voltage Vₜₕ from the rest voltage Vᵣₑₛₜ decreases, so the fire frequency increases. Meanwhile, as the width ΔV_{win} of hysteresis becomes smaller, the time for the second NPN device 20 to maintain the low-resistance state (LRS) becomes shorter, and the amount of charge charged in the first capacitor 40 decreases, so a height hₛ of the spike decreases. When the gate voltage V_{G} is too large, the width ΔV_{win} of hysteresis and the height hₛ of the spike become too small, and the first NPN device 10 and the second NPN device 20 are not converted into the high-resistance state (HRS), so the integration operation may not be performed. As a result, the fire frequency should be controlled by regulating the gate voltage V_{G} within an appropriate range.

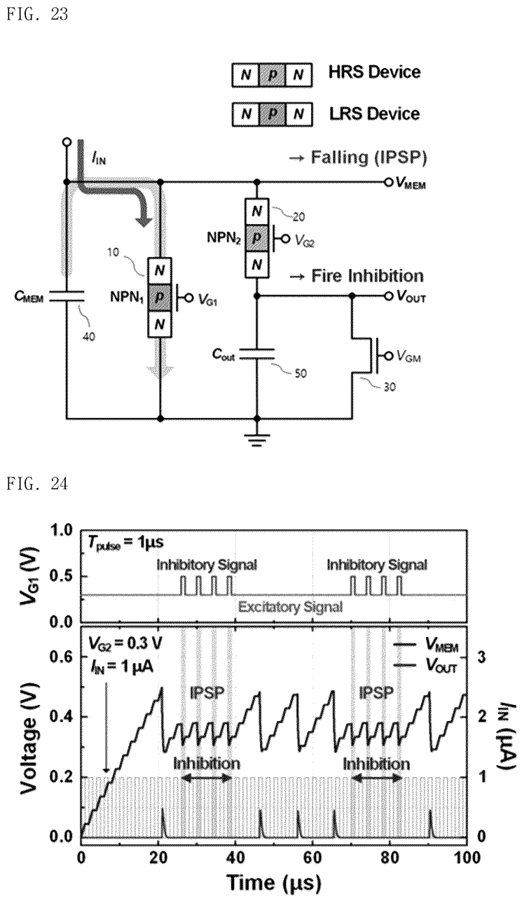

FIG. 23 is a diagram for describing the mechanism by which an inhibitory post-synaptic potential (IPSP) is generated in the integrate-and-fire neuron circuit according to the embodiment of the present invention.

The inhibitory post-synaptic potential (IPSP) refers to a phenomenon in which a membrane potential of a neuron increases and moves away from a threshold due to an inhibitory signal from a synapse. In biological neurons, the inhibitory post-synaptic potential (IPSP) refers to hyperpolarization in which the post-synaptic membrane potential becomes more negative than the rest membrane potential, and in the membrane, when the excitatory post-synaptic potential (EPSP) and inhibitory post-synaptic potential (IPSP) are temporally summed and reaches a membrane threshold, a spike is fired.

The only difference between the integrate-and-fire neuron circuit according to the embodiment of the present invention and the biological neurons is that the inhibitory post-synaptic potential (IPSP) occurs at a voltage greater than the rest membrane potential. The integrate-and-fire neuron circuit according to the embodiment of the present invention implemented a fire inhibition operation by temporal summation of the excitatory post-synaptic potential (EPSP) and the inhibitory post-synaptic potential (IPSP) of biological neurons at a voltage greater than the rest membrane potential.

In addition to the method of reducing the synaptic weight by introducing the inhibitory post-synaptic potential (IPSP), it is possible to effectively inhibit the spike fire simply by regulating the gate voltage of the neuron, and it is possible to expect the increase in the energy efficiency of the entire system through a sparse fire of spike.

The inhibitory post-synaptic potential (IPSP) is achieved by setting the gate voltage V_{G1} of the first NPN device 10 to be greater than the gate voltage V_{G2} of the second NPN device 20. Since the gate voltage V_{G1}>gate voltage V_{G2}, a latch-up voltage V_{LU1} of the first NPN device 10 is smaller than a latch-up voltage V_{LU2} of the second NPN device 20. The spike is fired when the second NPN device 20 is converted into the low-resistance state (LRS) and reaches the latch-up voltage V_{LU2}, which is a voltage capable of charging the second capacitor 50. In the membrane voltage V_{MEM}<latch-up voltage V_{LU2} step, that is, the integration operation step, when applying the gate voltage V_{G1} greater than the gate voltage V_{G2} in the integration operation step, if the membrane voltage V_{MEM} is greater than the latch-up voltage V_{LU1}, the first NPN device 10 is converted into the low-resistance state (LRS), so the charge charged in the second capacitor 50 flows out through the first NPN device 10.

As a result, the membrane voltage V_{MEM} fails to reach the latch-up voltage V_{LU2} and begins to decrease, so the fire of the output voltage Vₒᵤₜ is inhibited. When the gate voltage V_{G1} of the same magnitude as the gate voltage V_{G2} is applied to the gate of the first NPN device 10 at the membrane voltage V_{MEM}<latch-up voltage V_{LU2}, as the membrane voltage V_{MEM} increases, the excitatory post-synaptic potential (EPSP) approaches the latch-up voltage V_{LU2}, which is the fire threshold voltage. Meanwhile, when the gate voltage V_{G1} greater than the gate voltage V_{G2} is applied to the gate of the first NPN device 10, the inhibitory post-synaptic potential (IPSP) in which the membrane voltage V_{MEM} decreases and moves away from the latch-up voltage V_{LU2} is formed. The excitatory post-synaptic potential (EPSP) and the inhibitory post-synaptic potential (IPSP) are temporally summed in the first capacitor 40 to fire the output voltage Vₒᵤₜ when the membrane voltage V_{MEM} reaches the latch-up voltage V_{LU2}.

FIG. 24 is a timing diagram of an operation in which an excitatory post-synaptic potential (EPSP) and the inhibitory post-synaptic potential (IPSP) are added when a synaptic inhibitory signal is input to the integrate-and-fire neuron circuit according to the embodiment of the present invention.

Except when the synaptic inhibitory signal is input, the gate voltage V_{G1} should maintain the same magnitude as the gate voltage V_{G2} to implement the excitatory post-synaptic potential (EPSP) and fire and initialization operations in the integration step. When 0.3V of the same magnitude as the gate voltage V_{G2} is applied to the gate voltage V_{G1} at the membrane voltage V_{MEM}<latch-up voltage V_{LU2}, if the synaptic current signal I_{IN} is input, the excitatory post-synaptic potential (EPSP) occurs, which increases the membrane voltage V_{MEM}, and when the synaptic inhibitory signal of 0.5V, which is greater than the gate voltage V_{G2} of 0.3V, is input to the gate voltage V_{G1}, regardless of the input of the synaptic current signal I_{IN}, the inhibitory post-synaptic potential IPSP occurs in which the membrane voltage V_{MEM} decreases. The inhibitory post-synaptic potential IPSP caused by the synaptic inhibitory signal is summed with the excitatory post-synaptic potential (EPSP) within the first capacitor 40, and thus, the fire of the output voltage Vₒᵤₜ is inhibited for a certain period of time.

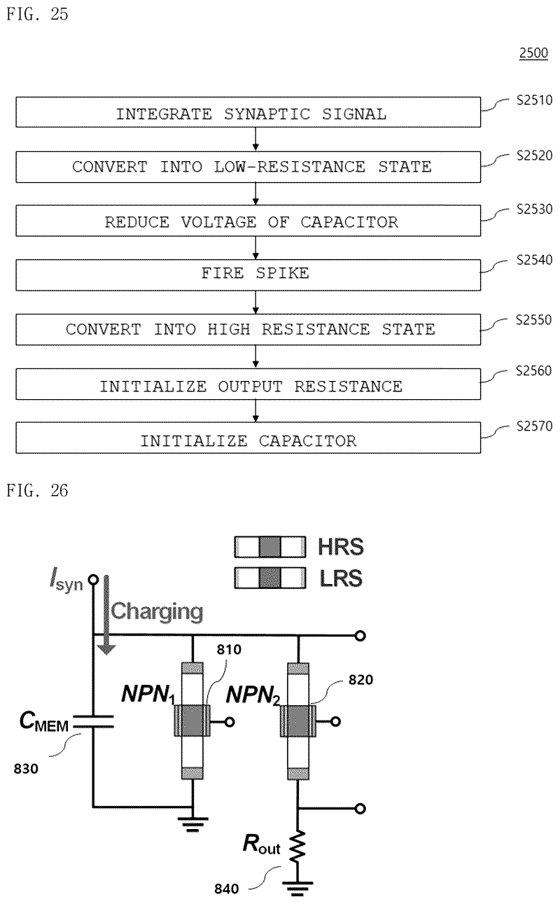

FIG. 25 is a flowchart for describing a process of an operation method of an integrate-and-fire neuron circuit according to an another embodiment of the present invention.

As illustrated in FIG. 25, the operation method of the integrate-and-fire neuron circuit according to the present invention includes a synaptic signal integration step (S2510), a low-resistance state conversion step (S2520), and a capacitor voltage reduction step (S2530), a spike firing step (S2540), a high-resistance state conversion step (S2550), an output resistor initialization step (S2560), and a capacitor initialization step (S2570).

In the synaptic signal integration step (S2510), the synaptic current signal input to the capacitor is integrated to increase the potentials of the anode terminal of the first NPN device and the anode terminal of the second NPN device.

In the low-resistance state conversion step (S2520), the voltage of the capacitor reaches the latch-up voltage of the first NPN device and the second NPN device, so the first NPN device and the second NPN device are converted into the low-resistance state (LRS).

In the capacitor voltage reduction step (S2530), the charge charged in the capacitor is discharged through the first NPN device and the second NPN device converted into the low-resistance state (LRS) to reduce the voltage of the capacitor.

In the spike firing step (S2540), the voltage of the output resistor increases by the second NPN device converted into the low-resistance state (LRS) to fire the spike.

In the high-resistance state conversion step (S2550), the second NPN device is converted into the high-resistance state (HRS) at the voltage of the capacitor greater than that of the first NPN device due to the increase in the voltage of the output resistor.

In the output resistor initialization step (S2560), the output resistor is initialized by decreasing the voltage of the output resistor due to the increase in the resistance of the second NPN device.

In the capacitor initialization step (S2570), the capacitor is initialized by decreasing the voltage of the capacitor to a latch-down voltage which is a voltage at which both the first NPN device and the second NPN device are converted into the high-resistance state (HRS).

FIGS. 26 to 28 are diagrams for describing an integrate-and-fire operation mechanism of the integrate-and-fire neuron circuit according to the embodiment of the present invention.

FIG. 26 is a diagram illustrating an integration operation mechanism of the integrate-and-fire neuron circuit according to the embodiment of the present invention.

The synaptic current signal I_{IN} is input to the node where the first NPN device 810, the second NPN device 820, and the capacitor 830 are connected in parallel. The integrate-and-fire operation is achieved by applying the same gate voltage V_{G1}=V_{G2} to the first NPN device 810 and the second NPN device 820, and a latch-up phenomenon occurs where the conversion into the low-resistance state (LRS) occurs at the same magnitude of membrane voltage V_{MEM}. The first NPN device 810 and the second NPN device 820 maintain the high-resistance state (HRS) before the membrane voltage V_{MEM} reaches a latch-up voltage V_{LU} of the first NPN device 810 and the second NPN device 820.

Therefore, when the membrane voltage V_{MEM}<latch-up voltage V_{LU}, the synaptic current signal I_{IN} hardly flows into the first NPN device 810 and the second NPN device 820 in the high-resistance state (HRS), and is mostly charged and integrated in the capacitor 830 connected in parallel. While the synaptic current signal I_{IN} is input, the membrane voltage V_{MEM} increases over time until it reaches the latch-up voltage V_{LU}.

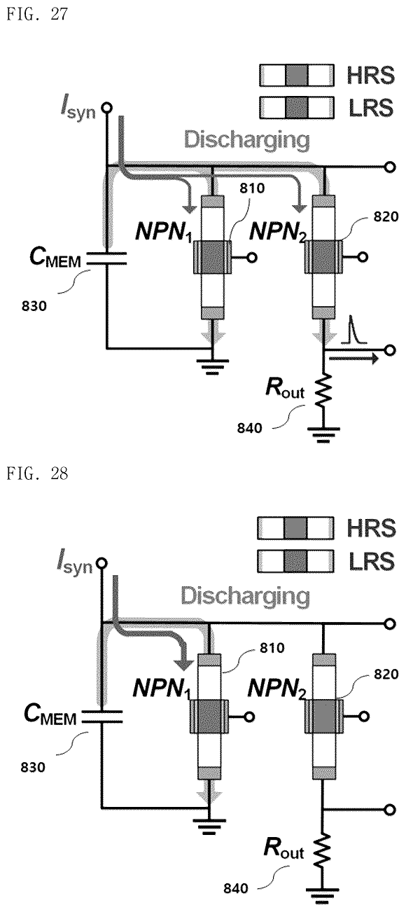

FIG. 27 is a diagram illustrating a fire operation mechanism of the integrate-and-fire neuron circuit according to the embodiment of the present invention.

The firing operation occurs when the membrane voltage V_{MEM} reaches the latch-up voltage V_{LU} and the first NPN device 810 and the second NPN device 820 are simultaneously converted into the low-resistance state (LRS). The membrane voltage V_{MEM} begins to decrease as the charge integrated in the capacitor 830, which is the membrane capacitor, flows out through the first NPN device 810 and the second NPN device 820 converted into the low-resistance state (LRS).

At the same time, the charge flowing out through the second NPN device 820 is charged in the output resistor 840, so an output voltage Vₒᵤₜ rapidly increases to fire the spike. While the membrane voltage V_{MEM} decreases, a voltage V_{AC} applied across the second NPN device 820 becomes smaller than that of the first NPN device 810 due to the increasing output voltage Vₒᵤₜ. Therefore, the second NPN device 820 is converted into the high-resistance state (HRS) at the membrane voltage V_{MEM} greater than that of the first NPN device 810.

FIG. 28 is a diagram illustrating an initialization operation mechanism of the integrate-and-fire neuron circuit according to the embodiment of the present invention.

The output voltage Vₒᵤₜ is initialized by decreasing again by voltage distribution as the second NPN device is converted into the high resistance state (HRS). Meanwhile, the output resistor is initialized by reducing the membrane voltage V_{MEM} to the latch-down voltage V_{LD} which is the voltage at which both the first NPN device 810 and the second NPN device 820 are converted into the high-resistance state (HRS) by the first NPN device in the low-resistance state (LRS).

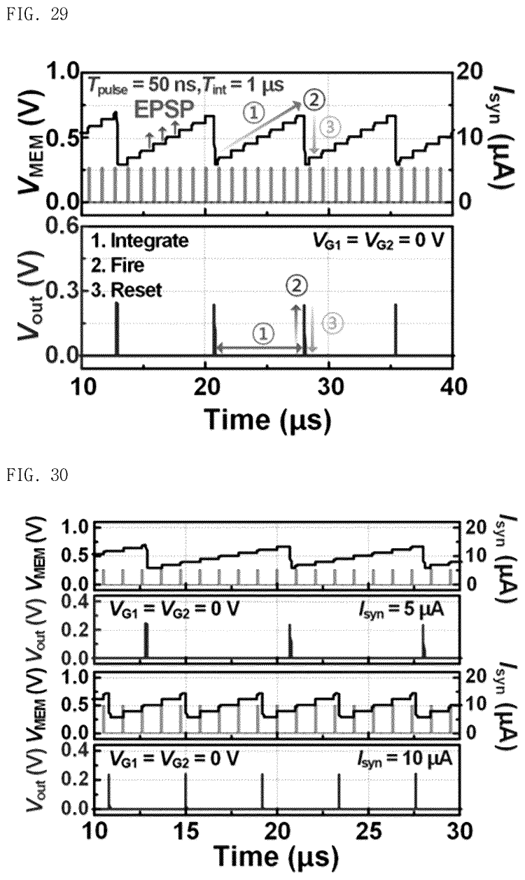

FIG. 29 is a timing diagram of the integrate-and-fire operation of the integrate-and-fire neuron circuit according to the embodiment of the present invention. In the embodiment illustrated in FIG. 29, when the synaptic current signal I_{IN} having a magnitude of 5 μA is input to the integrate-and-fire neuron circuit 100 according to an embodiment at intervals of 1 μs, the timing of the integrate-and-fire operation is illustrated.

The fire-and-integrate operation is achieved by applying the same gate voltage to the first NPN device 810 and the second NPN device 820. When the membrane voltage V_{MEM}<latch-up voltage V_{LU}, both the first NPN device 810 and the second NPN device 820 maintain the high-resistance state (HRS), so the synaptic current signal I_{IN} may charge the capacitor 830. In this way, while the synaptic current signal I_{IN} input, an excitatory post-synaptic potential increasing until the membrane voltage V_{MEM} reaches the latch-up voltage V_{LU} is achieved. Here, the excitatory post-synaptic potential (EPSP) refers to the phenomenon in which a membrane potential of a neuron increases due to an excitatory signal from a synapse and approaches a threshold.

The membrane voltage V_{MEM} begins to decrease at the latch-up voltage V_{LU} at which the first NPN device 810 and the second NPN device 820 are converted into the low-resistance state (LRS), and decreases to the latch-down voltage V_{LD} where the first NPN device 810 and the second NPN device 820 are converted into the high-resistance state (HRS).

Comparing with the anode current-anode voltage output curve of FIG. 13, it can be seen that a difference between a threshold voltage Vₜₕ and a rest voltage Vᵣₑₛₜ of a neuron is equal to a width ΔV_{win} of hysteresis of the NPN device according to one embodiment.

FIG. 30 is a timing diagram of the integrate-and-fire operation according to various synaptic current magnitudes of the integrate-and-fire neuron circuit according to the embodiment of the present invention. In the embodiment illustrated in FIG. 30, when a current pulse having a width of 50 ns is input at intervals of 1 μs by adjusting the magnitude of the synaptic current signal I_{IN}, the timing of the integrate-and-fire operation of the neuron circuit according to one embodiment is illustrated.

The magnitude of the synaptic current signal I_{IN} is proportional to the size of the weight stored in the synapse. Referring to FIG. 30, it can be seen that as the size of the synaptic current signal I_{IN} increases, the number of current pulses required to reach the threshold voltage Vₜₕ from the rest voltage Vᵣₑₛₜ decreases, and thus the fire frequency increases.

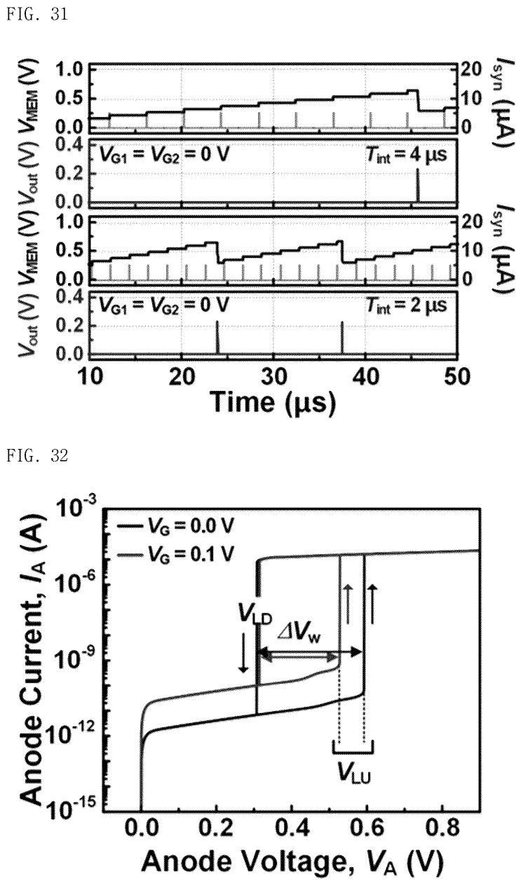

FIG. 31 is a timing diagram of the integrate-and-fire operation according to an interval between pulses of various synaptic current magnitudes in the integrate-and-fire neuron circuit according to the embodiment of the present invention. In the embodiment illustrated in FIG. 31, when a current pulse having a width of 50 ns is input at a certain magnitude of 5 μA by adjusting a size of an interval tᵢₙₜ between the synaptic current pulses, the timing of the integrate-and-fire operation of the neuron circuit according to one embodiment is illustrated.

Since the synaptic current signal I_{IN} is input when the synapse receives a spike from the pre-synaptic neuron, the interval tᵢₙₜ between the synaptic current pulses is inversely proportional to the fire frequency of the pre-synaptic neuron. As the size of the interval tᵢₙₜ between the synaptic current pulses decreases, the time required to reach the threshold voltage Vₜₕ from the rest voltage Vᵣₑₛₜ decreases, so the fire frequency increases.

FIG. 32 is an anode current-anode voltage output curve according to various gate voltages of the NPN device of the integrate-and-fire neuron circuit according to the embodiment of the present invention. In the embodiment illustrated in FIG. 32, a gate-cathode voltage V_{GC} was tested by varying between 0.0V and 0.1V.

As the gate voltage V_{G} applied to the NPN device increases, the energy barrier of the PN⁺ junction is lowered, so electrons from the high-concentration N-type semiconductor N⁺ easily flow into the anode beyond the P-type semiconductor. Therefore, as the gate voltage V_{G} increases, the NPN device is converted into the low-resistance state (LRS) by a feedback loop at a lower voltage. When the same gate voltage V_{G} of 0.1V is applied to the first NPN device 810 and the second NPN device 820, a width ΔV_{win} of hysteresis decreased by 0.06V compared to when the same gate voltage V_{G} of 0.0V is applied.

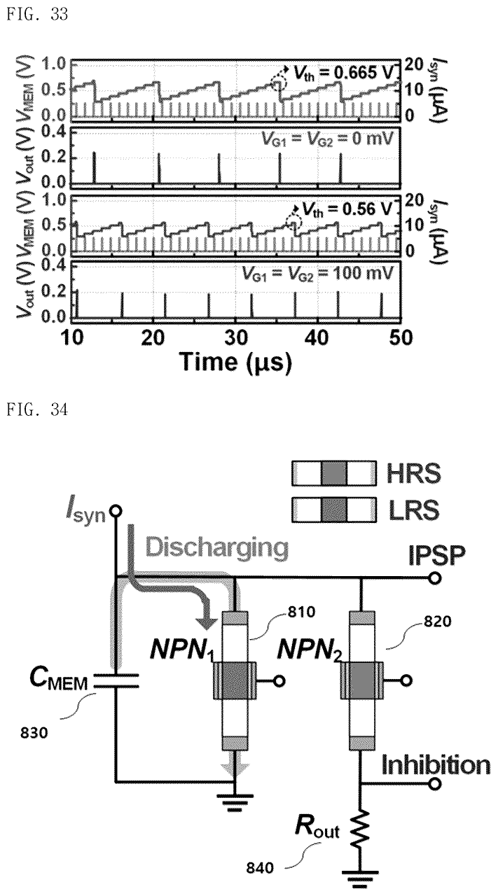

FIG. 33 is a timing diagram of the integrate-and-fire operation according to the gate voltage of the integrate-and-fire neuron circuit according to the embodiment of the present invention. In the embodiment illustrated in FIG. 33, the timing of the integrate-and-fire operation when a current pulse having a magnitude of 500 μA and a width of 50 ns is input at intervals of 1 μs under the conditions of V_{G1}=V_{G2}=0.0V and 0.1V is illustrated.

As the width ΔV_{win} of hysteresis becomes smaller, the number of current pulses required to reach the threshold voltage Vₜₕ from the rest voltage Vᵣₑₛₜ decreases, so the fire frequency increases. Meanwhile, as the width ΔV_{win} of hysteresis becomes smaller, the time for the first NPN device 810 and the second NPN device 820 to maintain the low-resistance state (LRS) becomes shorter, so the energy consumed per spike decreases.

FIG. 34 is a diagram for describing the mechanism by which an inhibitory post-synaptic potential (IPSP) is generated in the integrate-and-fire neuron circuit according to the embodiment of the present invention.

The inhibitory post-synaptic potential (IPSP) refers to a phenomenon in which a membrane potential of a neuron increases and moves away from a threshold due to an inhibitory signal from a synapse. In biological neurons, the inhibitory post-synaptic potential (IPSP) refers to hyperpolarization in which the post-synaptic membrane potential becomes more negative than the rest membrane potential, and in the membrane, when the excitatory post-synaptic potential (EPSP) and inhibitory post-synaptic potential (IPSP) are temporally summed and reaches a membrane threshold, a spike is fired.

The only difference between the integrate-and-fire neuron circuit according to the embodiment of the present invention and the biological neurons is that the inhibitory post-synaptic potential (IPSP) occurs at a voltage greater than the rest membrane potential. The integrate-and-fire neuron the circuit according to embodiment of the present invention implemented a fire inhibition operation by temporal summation of the excitatory post-synaptic potential (EPSP) and the inhibitory post-synaptic potential (IPSP) of biological neurons at a voltage greater than the rest membrane potential.

In addition to the method of reducing the synaptic weight by introducing the inhibitory post-synaptic potential (IPSP), it is possible to effectively inhibit the spike fire simply by regulating the gate voltage of the neuron, and it is possible to expect the increase in the energy efficiency of the entire system through a sparse fire of spike.

The inhibitory post-synaptic potential (IPSP) is achieved by setting the gate voltage V_{G1} of the first NPN device 810 to be greater than the gate voltage V_{G2} of the second NPN device 820. Since the gate voltage V_{G1}>gate voltage V_{G2}, a latch-up voltage V_{LU1} of the first NPN device 810 is smaller than a latch-up voltage V_{LU2} of the second NPN device 820. The spike is fired when the second NPN device 820 is converted into the low-resistance state (LRS) and reaches the latch-up voltage V_{LU2}, which is a voltage capable of charging the output resistor 840. In the membrane voltage V_{MEM}<latch-up voltage V_{LU2} step, that is, the integration operation step, when applying the gate voltage V_{G1} greater than the gate voltage V_{G2} in the integration operation step, if the membrane voltage V_{MEM} is greater than the latch-up voltage V_{LU1}, the first NPN device 810 is converted into the low-resistance state (LRS), so the spike occurs through the output resistor 840.

As a result, the membrane voltage V_{MEM} fails to reach the latch-up voltage V_{LU2} and begins to decrease, so the fire of the output voltage Vₒᵤₜ is inhibited. When the gate voltage V_{G1} of the same magnitude as the gate voltage V_{G2} is applied to the gate of the first NPN device 810 at the membrane voltage V_{MEM}<latch-up voltage V_{LU2}, as the membrane voltage V_{MEM} increases, the excitatory post-synaptic potential (EPSP) approaches the latch-up voltage V_{LU2}, which is the fire threshold voltage. Meanwhile, when the gate voltage V_{G1} greater than the gate voltage V_{G2} is applied to the gate of the first NPN device 810, the inhibitory post-synaptic potential (IPSP) in which the membrane voltage V_{MEM} decreases and moves away from the latch-up voltage V_{LU2} is formed. The excitatory post-synaptic potential (EPSP) and the inhibitory post-synaptic potential (IPSP) are temporally summed in the capacitor 830 to fire the output voltage Vₒᵤₜ when the membrane voltage V_{MEM} reaches the latch-up voltage V_{LU2}.

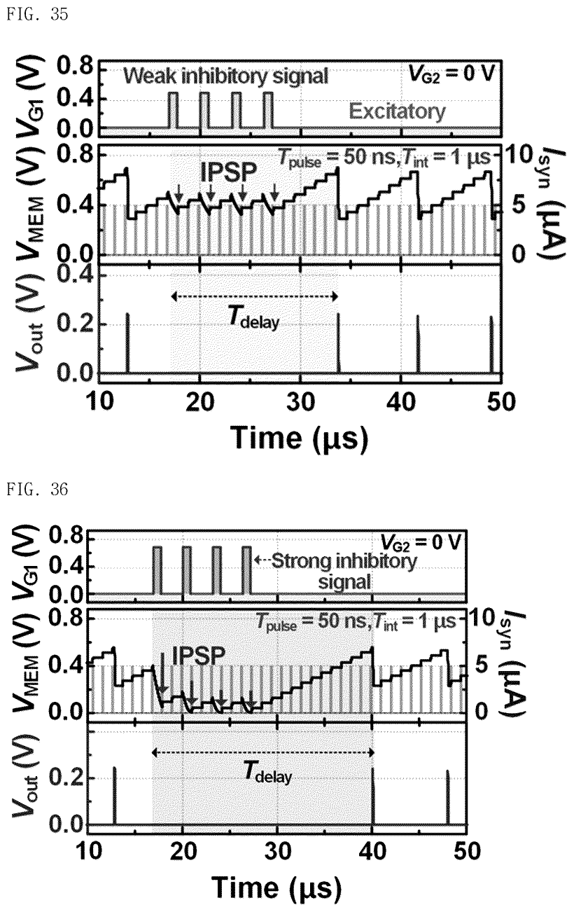

FIG. 35 is a timing diagram of an operation in which an excitatory post-synaptic potential (EPSP) and the inhibitory post-synaptic potential (IPSP) are added when a synaptic inhibitory signal is input to the integrate-and-fire neuron circuit according to the embodiment of the present invention.

Except when the synaptic inhibitory signal is input, the gate voltage V_{G1} should maintain the same magnitude as the gate voltage V_{G2} to implement the excitatory post-synaptic potential (EPSP) and fire and initialization operations in the integration step. When 0.0V of the same magnitude as the gate voltage V_{G2} is applied to the gate voltage V_{G1} at the membrane voltage V_{MEM}<latch-up voltage V_{LU2}, if the synaptic current signal I_{IN} is input, the excitatory post-synaptic potential (EPSP) occurs, which increases the membrane voltage V_{MEM}, and when the synaptic inhibitory signal of 0.5V, which is greater than the gate voltage V_{G2} of 0.0V, is input to the gate voltage V_{G1}, regardless of the input of the synaptic current signal I_{IN}, the inhibitory post-synaptic potential IPSP occurs in which the membrane voltage V_{MEM} decreases. The inhibitory post-synaptic potential IPSP caused by the synaptic inhibitory signal is summed with the excitatory post-synaptic potential (EPSP) within the capacitor 830, and thus, the fire of the output voltage Vₒᵤₜ is inhibited for a certain period of time.

FIG. 36 is a timing diagram of the operation of summing the excitatory post-synaptic potential (EPSP) and the inhibitory post-synaptic potential (IPSP) when a larger synaptic inhibitory signal is input to the integrate-and-fire neuron circuit according to an embodiment of the present invention.

When the synaptic inhibitory signal of 0.7V, which is greater than 0.5V, is input to the gate voltage V_{G1}, the strong inhibitory post-synaptic potential (IPSP) occurs, which causes a greater decrease in membrane voltage. The strong IPSP suppresses the output voltage Vₒᵤₜ from firing for a longer period of time.

Unlike a CMOS-based integrate-and-fire neuron circuit having a complex structure, an integrate-and-fire neuron circuit and an operation method thereof according to the present invention can be implemented to enable an integrate-and-fire operation with only a small number of devices using bistable resistance characteristics by a feedback loop of the same two heterojunction NPN devices.

In addition, it is possible to implement an inhibitory post-synaptic potential (IPSP) that reduces a neuron membrane potential by regulating a gate voltage of the same two NPN devices, and thus, it is possible to expect an increase in energy efficiency of the entire system by inhibiting excessive fire of neurons.

In addition, by adjusting a fire threshold point in addition to adjusting a weight of a synapse within a neuron itself by adjusting a gate voltage of a second NPN device, it is possible to perform efficient learning in a spiking neural network and by achieving a high fire frequency of up to 300 KHz, it is possible to perform high-speed learning and computation.

According to an NPN device of an integrate-and-fire neuron circuit according to the present invention, a P-type semiconductor is made of a material having a smaller band gap than a high-concentration N-type semiconductor to form a hysteresis of a magnitude of an LRS current sufficient for an integrate-and-fire operation at a low anode voltage due to a high impact ionization coefficient, charge mobility properties, and a band offset at a heterojunction, thereby reducing energy consumption of a circuit.

As described above, a neuron circuit according to the present invention enables an integrate-and-fire operation of neurons using only three transistors and two capacitors, or two transistors, one resistor and one capacitor, thereby increasing neuron integration in a system. In addition, it is possible to improve the efficiency of spiking neural network learning by controlling a fire threshold point of neurons through regulation of a gate voltage of the same two NPN devices, and it is possible to expect an increase in energy efficiency of the entire system through inhibition of excessive fire by implementing excitatory and inhibitory post-synaptic potentials.

What is claimed is:

1. An integrate-and-fire neuron circuit implementing an integrate-and-fire operation, comprising:
a first NPN device;
a second NPN device connected in parallel to the first NPN device;
a MOS transistor whose one end is connected to a cathode node of the second NPN device and other end is grounded;
a first capacitor connected in parallel to the first NPN device and the second NPN device; and
a second capacitor connected in parallel to the cathode node of the second NPN device together with the MOS transistor.

2. The integrate-and-fire neuron circuit of claim 1, wherein an anode terminal of the first NPN device is connected in parallel to the first capacitor and an anode terminal of the second NPN device, and a cathode end of the first NPN device is connected to a ground, and
the anode terminal of the second NPN device is connected in parallel to the first capacitor and the anode terminal of the first NPN device, and a cathode end of the second NPN device is connected in parallel to the MOS transistor and the second capacitor.

3. The integrate-and-fire neuron circuit of claim 2, wherein the first NPN device and the second NPN device include:
a first N-type semiconductor;
a P-type semiconductor whose one end is heterogeneously bonded to one end of the first N-type semiconductor;
a second N-type semiconductor whose one end is heterogeneously bonded to the other end of the P-type semiconductor;
a control gate formed on top of the P-type semiconductor;
an anode contacting the first N-type semiconductor through an ohmic junction;
a cathode contacting the second N-type semiconductor through the ohmic junction, and
the first N-type semiconductor and the second N-type semiconductor have a relatively higher concentration than the P-type semiconductor, and the P-type semiconductor has a smaller band gap than the first N-type semiconductor and the second N-type semiconductor.

4. An integrate-and-fire neuron circuit implementing an integrate-and-fire operation, comprising:
a first NPN device;
a second NPN device connected in parallel to the first NPN device;
a capacitor connected in parallel to the first NPN device and the second NPN device; and
an output resistor connected in series to the cathode node of the second NPN device.

5. The integrate-and-fire neuron circuit of claim 4, wherein an anode terminal of the first NPN device is connected in parallel to the capacitor and an anode terminal of the second NPN device, and a cathode end of the first NPN device is connected to a ground, and
the anode terminal of the second NPN device is connected in parallel to the capacitor and the anode terminal of the first NPN device, and a cathode end of the second NPN device is connected in series to the output resistor.

6. The integrate-and-fire neuron circuit of claim 5, wherein the first NPN device and the second NPN device include:
a first N-type semiconductor;
a P-type semiconductor whose one end is heterogeneously bonded to one end of the first N-type semiconductor;
a second N-type semiconductor whose one end is heterogeneously bonded to the other end of the P-type semiconductor;
a control gate formed on top of the P-type semiconductor;
an anode contacting the first N-type semiconductor through an ohmic junction;
a cathode contacting the second N-type semiconductor through the ohmic junction, and
the first N-type semiconductor and the second N-type semiconductor have a relatively higher concentration than the P-type semiconductor, and the P-type semiconductor has a smaller band gap than the first N-type semiconductor and the second N-type semiconductor.

7. An operation method of an integrate-and-fire neuron circuit according to claim 3, the operation method comprising:
integrating a synaptic current signal input to the first capacitor to increase potentials of the anode terminal of the first NPN device and the anode terminal of the second NPN device;
converting the first NPN device and the second NPN device into a low-resistance state (LRS) by allowing a voltage of the first capacitor to reach a latch-up voltage of the first NPN device and the second NPN device;
reducing the voltage of the first capacitor by discharging charge charged in the first capacitor through the first NPN device and the second NPN device converted into the low-resistance state (LRS);
firing a spike by increasing a voltage of the second capacitor by the second NPN device converted into the low-resistance state (LRS);
converting the second NPN device into a high-resistance state (HRS) at the voltage of the first capacitor greater than that of the first NPN device due to an increase in a voltage of the second capacitor so that charge is no longer charged in the second capacitor;
initializing the second capacitor by allowing the charge of the second capacitor to flow out through the MOS transistor and reducing the voltage of the second capacitor to 0V; and
initializing the first capacitor by reducing the voltage of the first capacitor to a latch-down voltage which is a voltage at which both the first NPN device and the second NPN device are converted into the high-resistance state (HRS).

8. The operation method of claim 7, wherein the synaptic current is input to an input node where the first capacitor, the anode terminal of the first NPN device, and the anode terminal of the second NPN device are connected in parallel, and when the voltage of the first capacitor reaches the latch-up voltage of the first NPN device and the second NPN device by the synaptic current, the spike fire and initialization operations are performed through the second capacitor and the MOS transistor.

9. The operation method of claim 7, wherein when the same gate voltage is applied to the first NPN device and the second NPN device, the first NPN device and the second NPN device have the same latch-up voltage,
the first NPN device and the second NPN device maintain the high-resistance state (HRS) before the voltage of the first capacitor reaches the latch-up voltage of the first NPN device and the second NPN device, and
the input synaptic current is charged in the first capacitor to perform an integration operation.

10. The operation method of claim 7, wherein the first NPN device and the second NPN device maintains the high-resistance state (HRS) by allowing only a few electrons of the high-concentration first N-type semiconductor to flow into the anode beyond a P-type semiconductor due to a high energy barrier of a PN⁺ junction.

11. The operation method of claim 7, wherein when the voltage of the first capacitor reaches the latch-up voltage of the first NPN device and the second NPN device, the first NPN device and the second NPN device are converted from the high-resistance state (HRS) into the low-resistance state (LRS), and
the voltage of the first capacitor decreases due to discharging of charge and the voltage of the second capacitor increases due to charging of charge to fire the spike.

12. The operation method of claim 7, wherein the first NPN device and the second NPN device generate stored holes by high-level impact ionization by allowing electrons from the high-concentration first N-type semiconductor to flow into the anode beyond the P-type semiconductor, and
the stored holes are converted into the low-resistance state (LRS) indicating a high current by repeating a feedback loop operation that lowers the PN⁺ barrier to supply more source electrons.

13. The operation method of claim 7, wherein the second NPN device is converted into the high-resistance state (HRS) at the voltage of the first capacitor greater than that of the first NPN device due to the increase in the voltage of the second capacitor so that the charge is no longer charged in the second capacitor.

14. The operation method of claim 7, wherein in the NPN device, the second capacitor is initialized by allowing the charge of the second capacitor to flow out through the MOS transistor to which the gate voltage is applied and reducing the voltage of the second capacitor to 0V.

15. The operation method of claim 7, wherein the first capacitor is initialized by reducing the voltage of the first capacitor to the latch-down voltage which is the voltage at which both the first NPN device and the second NPN device are converted into the high-resistance state (HRS) by the first NPN device in the low-resistance state (LRS).

16. The operation method of claim 7, wherein the first NPN device and the second NPN device are re-converted into the high-resistance state (HRS) indicating a low current by a negative feedback loop in which the PN⁺ barrier increases again due to recombination of the stored holes and a decrease in an impact ionization size.

17. The operation method of claim 7, wherein the spike fire has a fire frequency and height adjusted by regulating a gate voltage of the second NPN device.

18. The operation method of claim 7, wherein the spike fire has the fire frequency adjusted according to a magnitude of the input synaptic current and an interval between pulses of the synaptic current.

19. The operation method of claim 7, wherein when the same gate voltage is applied to the first NPN device and the second NPN device,
an initialization operation of the first capacitor is performed due to the first NPN device, and a spike fire operation is performed due to the second NPN device, and
the synaptic current is charged in the first capacitor before the spike fire operation due to the second NPN device is performed to implement an excitatory post-synaptic potential (EPSP) in which the voltage of the first capacitor increases.

20. The operation method of claim 19, wherein when a gate voltage greater than that of the second NPN device is applied to the first NPN device,
the first NPN device is converted into the low-resistance state (LRS) at a voltage lower than that of the first capacitor at which the spike fire due to the second NPN device occurs, and
an inhibitory post-synaptic potential (IPSP) is implemented in which the charge charged in the first capacitor flows out and the voltage of the first capacitor decreases.

21. The operation method of claim 7, wherein the P-type semiconductor of the first NPN device and the second NPN device is made of a material having a smaller band gap than the high-concentration first N-type semiconductor and second N-type semiconductor to have high charge mobility and an impact ionization coefficient, and thus, a latch-up phenomenon occurs at a small voltage due to a feedback loop, so the first NPN device and the second NPN device are converted into the LRS in which a high driving current flows.

22. The operation method of claim 21, wherein an energy band offset formed in a double PN junction of the first NPN device and the second NPN device inhibits an increase in a PN junction barrier due to a recombination of charges, so a magnitude of a driving current remains constant before latch-down, and
the first NPN device and the second NPN device form a hysteresis of a high driving current even at a small voltage to implement a stable initialization operation and reduce energy consumption.

23. An operation method of an integrate-and-fire neuron circuit according to claim 6, the operation method comprising:
integrating a synaptic current signal input to the capacitor to increase potentials of the anode terminal of the first NPN device and the anode terminal of the second NPN device;
converting the first NPN device and the second NPN device into a low-resistance state (LRS) by allowing a voltage of the capacitor to reach a latch-up voltage of the first NPN device and the second NPN device;
decreasing the voltage of the capacitor by discharging charge charged in the capacitor through the first NPN device and the second NPN device converted into the low-resistance state (LRS);
firing a spike by increasing a voltage of the output resistor by the second NPN device converted into the low-resistance state (LRS);
converting the second NPN device into a high-resistance state (HRS) at the voltage of the capacitor greater than that of the first NPN device due to an increase in a voltage of the output resistor;
initializing the output resistor by rapidly decreasing the voltage of the output resistor due to the second NPN element converted into the high resistance state (HRS); and
initializing the capacitor by reducing the voltage of the capacitor to a latch-down voltage which is a voltage at which both the first NPN device and the second NPN device are converted into the high-resistance state (HRS).

24. The operation method of claim 23, wherein the synaptic current is input to an input where the capacitor, the anode terminal of the first NPN device, and the anode terminal of the second NPN device are connected in parallel, and when the voltage of the capacitor reaches the latch-up voltage of the first NPN device and the second NPN device by the synaptic current, the spike fire and initialization operations are performed through the output resistor.

25. The operation method of claim 23, wherein when the same gate voltage is applied to the first NPN device and the second NPN device, the first NPN device and the second NPN device have the same latch-up voltage,
the first NPN device and the second NPN device maintain the high-resistance state (HRS) before the voltage of the capacitor reaches the latch-up voltage of the first NPN device and the second NPN device, and
the input synaptic current is charged in the capacitor to perform an integration operation.

26. The operation method of claim 23, wherein the first NPN device and the second NPN device maintains the high-resistance state (HRS) by allowing only a few electrons of the high-concentration first N-type semiconductor to flow into the anode beyond a P-type semiconductor due to a high energy barrier of a PN⁺ junction.

27. The operation method of claim 23, wherein when the voltage of the capacitor reaches the latch-up voltage of the first NPN device and the second NPN device, the first NPN device and the second NPN device are converted from the high-resistance state (HRS) into the low-resistance state (LRS), and
the voltage of the capacitor decreases due to flowing out of charge and the voltage of the output resistor increases due to voltage distribution to fire the spike.

28. The operation method of claim 23, wherein the first NPN device and the second NPN device generate stored holes by high-level impact ionization by allowing electrons from the high-concentration first N-type semiconductor to flow into the anode beyond the P-type semiconductor, and
the stored holes are converted into the low-resistance state (LRS) indicating a high current by repeating a feedback loop operation that lowers the PN⁺ barrier to supply more source electrons.

29. The operation method of claim 23, wherein the second NPN device is converted into the high-resistance state (HRS) at the voltage of the capacitor greater than that of the first NPN device due to the increase in the voltage of the output resistor.

30. The operation method of claim 23, wherein in the second NPN device, the voltage of the output resistor is initialized by decreasing due to the first NPN device converted into the high resistance state (HRS).

31. The operation method of claim 23, wherein the capacitor is initialized by reducing the voltage of the capacitor to the latch-down voltage which is the voltage at which both the first NPN device and the second NPN device are converted into the high-resistance state (HRS) by the first NPN device in the low-resistance state (LRS).

32. The operation method of claim 23, wherein the first NPN device and the second NPN device are re-converted into the high-resistance state (HRS) indicating a low current by a negative feedback loop in which the PN⁺ barrier increases again due to recombination of the stored holes and a decrease in an impact ionization size.

33. The operation method of claim 23, wherein the spike fire has a fire frequency and height adjusted by regulating a gate voltage of the second NPN device.

34. The operation method of claim 23, wherein the spike fire has the fire frequency adjusted according to a magnitude of the input synaptic current and an interval between pulses of the synaptic current.

35. The operation method of claim 23, wherein when the same gate voltage is applied to the first NPN device and the second NPN device,
an initialization operation of the capacitor is performed due to the first NPN device, and a spike fire operation is performed due to the second NPN device, and
the synaptic current is charged in the capacitor before the spike fire operation due to the second NPN device is performed to implement an excitatory post-synaptic potential (EPSP) in which the voltage of the capacitor increases.

36. The operation method of claim 35, wherein when a gate voltage greater than that of the second NPN device is applied to the first NPN device,
the first NPN device is converted into the low-resistance state (LRS) at a voltage lower than that of the capacitor at which the spike fire due to the second NPN device occurs, and
an inhibitory post-synaptic potential (IPSP) is implemented in which the charge charged in the capacitor flows out and the voltage of the capacitor decreases.

37. The operation method of claim 36, wherein when the gate voltage greater than that of the second NPN device is applied to the first NPN device, as the gate voltage applied to the first NPN device increases, the strong inhibitory post-synaptic potential (IPSP) may be realized in which the charge charged in the capacitor flows out more and the voltage of the capacitor decreases more.

38. The operation method of claim 23, wherein the P-type semiconductor of the first NPN device and the second NPN device is made of a material having a smaller band gap than the high-concentration first N-type semiconductor and second N-type semiconductor to have high charge mobility and an impact ionization coefficient, and thus, a latch-up phenomenon occurs at a small voltage due to a feedback loop, so the first NPN device and the second NPN device are converted into the LRS in which a high driving current flows.

39. The operation method of claim 38, wherein an energy band offset formed in a double PN junction of the first NPN device and the second NPN device inhibits an increase in a PN junction barrier due to a recombination of charges, so a magnitude of a driving current remains constant before latch-down, and
the first NPN device and the second NPN device form a hysteresis of a high driving current even at a small voltage to implement a stable initialization operation and reduce energy consumption.
